(19) United States
(12) Patent Application Publication
(10) Pub. No.: US 2023/0403881 A1
(43) Pub. Date: Dec. 14, 2023

(54) DISPLAY PANEL, DATA PROCESSING DEVICE, AND METHOD FOR MANUFACTURING DISPLAY PANEL

(71) Applicant: Semiconductor Energy Laboratory Co., Ltd., Atsugi-shi, Kanagawa-ken (JP)

(72) Inventors: Shunpei YAMAZAKI, Setagaya (JP); Shingo EGUCHI, Atsugi (JP); Satoshi SEO, Sagamihara (JP); Kenichi OKAZAKI, Atsugi (JP)

(21) Appl. No.: 18/033,846

(22) PCT Filed: Nov. 5, 2021
(86) PCT No.: PCT/IB2021/060241

§ 371 Date: Apr. 26, 2023

(30) Foreign Application Priority Data
Nov. 17, 2020 (JP) 2020-191144
Nov. 27, 2020 (JP) 2020-196998
Dec. 7, 2020 (JP) 2020-202373

(51) Int. Cl. H10K 59/122; H10K 59/38; H10K 59/12

(52) U.S. Cl. CPC H10K 59/122; H10K 59/38; H10K 59/1201

(57) ABSTRACT

A novel display panel that is highly convenient, useful, or reliable is provided. The display panel includes a first light-emitting device, a second light-emitting device, and a partition, the first light-emitting device includes a first electrode, a second electrode, and a first layer, and the first layer includes a region interposed between the second electrode and the first electrode. The first layer contains a first material having a hole-transport property and a first substance having an acceptor property, and has a predetermined electrical resistivity. The second light-emitting device includes a third electrode, a fourth electrode, and a second layer, and the second layer includes a region interposed between the fourth electrode and the third electrode. The second layer contains the first material having the hole-transport property and the first substance having the acceptor property, and the second layer includes a first gap between the second layer and the first layer. The first gap includes a region overlapping with the partition, and the first gap prevents electrical continuity between the first layer and the second layer.

### TECHNICAL FIELD

One embodiment of the present invention relates to a display panel, a method for manufacturing a display panel, a data processing device, or a semiconductor device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Thus, more specifically, examples of the technical field of one embodiment of the present invention disclosed in this specification include a semiconductor device, a display device, a light-emitting device, a power storage device, a memory device, a driving method thereof, and a manufacturing method thereof.

### BACKGROUND ART

A method for manufacturing an organic EL display in which a light-emitting layer can be formed without using a fine metal mask is known. An example of the method is a method for manufacturing an organic EL display (Patent Document 1). The method includes a step of forming a first light-emitting layer as a continuous film crossing a display region including an electrode array by deposition of a first luminescent organic material containing a mixture of a host material and a dopant material over the electrode array that is formed over an insulating substrate and includes a first pixel electrode and a second pixel electrode; a step of irradiating part of the first light-emitting layer positioned over the second pixel electrode with ultraviolet light while part of the first light-emitting layer positioned over the first pixel electrode is not irradiated with ultraviolet light; a step of forming a second light-emitting layer as a continuous film crossing a display region by deposition of a second luminescent organic material, which contains a mixture of a host material and a dopant material but differs from the first luminescent organic material, over the first light-emitting layer; and a step of forming a counter electrode over the second light-emitting layer.

### REFERENCE

### Patent Document

[Patent Document 1] Japanese Published Patent Application No. 2012-160473

### SUMMARY OF THE INVENTION

### Problems to be Solved by the Invention

An object of one embodiment of the present invention is to provide a novel display panel that is highly convenient, useful, or reliable. Another object is to provide a method for manufacturing a novel display panel that is highly convenient, useful, or reliable. Another object is to provide a novel data processing device that is highly convenient, useful, or reliable. Another object is to provide a novel display panel, a method for manufacturing a novel display panel, a novel data processing device, or a novel semiconductor device.

Note that the description of these objects does not preclude the existence of other objects. One embodiment of the present invention does not have to achieve all of these objects. Other objects are apparent from and can be derived from the description of the specification, the drawings, the claims, and the like.

### Means for Solving the Problems

(1) One embodiment of the present invention is a display panel including a first light-emitting device, a second light-emitting device, and a partition.

The first light-emitting device includes a first electrode, a second electrode, and a first layer, and the first layer includes a region interposed between the second electrode and the first electrode.

The first layer contains a first material having a hole-transport property and a first substance having an acceptor property, and the first layer has an electrical resistivity greater than or equal to 1×10² [Ω·cm] and less than or equal to 1×10⁸ [Ω·cm].

The second light-emitting device includes a third electrode, a fourth electrode, and a second layer, and the second layer includes a region interposed between the fourth electrode and the third electrode.

The second layer contains the first material having the hole-transport property and the first substance having the acceptor property, and the second layer includes a first gap between the second layer and the first layer.

The first gap includes a region overlapping with the partition, and the first gap prevents electrical continuity between the first layer and the second layer.

(2) Another embodiment of the present invention is a display panel including a first light-emitting device, a second light-emitting device, and a partition.

The first light-emitting device includes a first electrode, a second electrode, a first unit, and a first layer, the second electrode overlaps with the first electrode, and the first unit includes a region interposed between the second electrode and the first electrode. In addition, the first layer includes a region interposed between the first unit and the first electrode.

The first layer contains a first material having a hole-transport property and a first substance having an acceptor property, and the first layer has an electrical resistivity greater than or equal to 1×10² [Ω·cm] and less than or equal to 1×10⁸ [Ω·cm].

The second light-emitting device includes a third electrode, a fourth electrode, a second unit, and a second layer, the fourth electrode overlaps with the third electrode, and the second unit includes a region interposed between the fourth electrode and the third electrode. In addition, the second layer includes a region interposed between the second unit and the first electrode.

The second layer contains the first material having the hole-transport property and the first substance having the acceptor property, and the second layer includes a first gap between the second layer and the first layer.

The partition includes a first opening portion and a second opening portion, the first opening portion overlaps with the first electrode, and the second opening portion overlaps with the third electrode. The partition overlaps with the first gap between the first opening portion and the second opening portion.

Thus, electrical continuity between the first layer and the second layer is prevented. A phenomenon in which current flows between the first electrode and the fourth electrode through the first layer and the second layer can be inhibited. A phenomenon in which current flows between the third electrode and the second electrode through the first layer and the second layer can be inhibited. In addition, occurrence of a crosstalk phenomenon between the first light-emitting device and the second light-emitting device can be inhibited. As a result, a novel display panel that is highly convenient, useful, or reliable can be provided.

(3) Another embodiment of the present invention is the above-described display panel in which the first light-emitting device includes a third unit and a first intermediate layer. The third unit includes a region interposed between the second electrode and the first unit, and the first intermediate layer includes a region interposed between the third unit and the first unit.

The first intermediate layer contains a second material having a hole-transport property and a second substance having an acceptor property, and the first intermediate layer has an electrical resistivity greater than or equal to 1×10² [Ω·cm] and less than or equal to 1×10⁸ [Ω·cm].

The second light-emitting device includes a fourth unit and a second intermediate layer, and the fourth unit includes a region interposed between the fourth electrode and the second unit. The second intermediate layer includes a region interposed between the fourth unit and the second unit.

The second intermediate layer contains the second material having the hole-transport property and the second substance having the acceptor property, and the second intermediate layer includes a second gap between the second intermediate layer and the first intermediate layer.

The partition overlaps with the second gap between the first opening portion and the second opening portion.

Thus, a phenomenon in which current flows between the first electrode and the fourth electrode through the first layer, the second layer, the third intermediate layer, and the fourth intermediate layer can be inhibited. A phenomenon in which current flows between the third electrode and the second electrode through the first layer and the second layer can be inhibited. In addition, occurrence of a crosstalk phenomenon between the first light-emitting device and the second light-emitting device can be inhibited. As a result, a novel display panel that is highly convenient, useful, or reliable can be provided.

(4) Another embodiment of the present invention is the above-described display panel in which the first material having the hole-transport property is an aromatic amine compound or an organic compound having a π-electron rich heteroaromatic ring, and the first substance having the acceptor property is an organic compound containing fluorine or a cyano group or a transition metal oxide.

Thus, holes can be supplied from the anode side to the cathode side. Note that the second layer of the second light-emitting device is separated from the first layer of the first light-emitting device, whereby a crosstalk phenomenon can be inhibited. As a result, a novel display panel that is highly convenient, useful, or reliable can be provided.

(5) Another embodiment of the present invention is the above-described display panel including a first insulating film. The second electrode is interposed between the first insulating film and the first electrode, and the fourth electrode is interposed between the first insulating film and the third electrode.

Thus, diffusion of impurities existing around the first light-emitting device into the first light-emitting device can be inhibited. In addition, diffusion of impurities existing around the second light-emitting device into the second light-emitting device can be inhibited. As a result, a novel display panel that is highly convenient, useful, or reliable can be provided.

(6) Another embodiment of the present invention is the above-described display panel in which the first layer includes a first sidewall, and the second layer includes a second sidewall. The second sidewall faces the first sidewall, and the first gap is interposed between the second sidewall and the first sidewall. The first insulating film is in contact with the first sidewall and the second sidewall.

(7) Another embodiment of the present invention is the above-described display panel in which the first insulating film is in contact with the partition.

(8) Another embodiment of the present invention is the above-described display panel in which the first insulating film includes a second insulating film and a third insulating film.

The second insulating film is interposed between the third insulating film and the second electrode, and the second insulating film is interposed between the third insulating film and the fourth electrode. The second insulating film contains oxygen and aluminum, and the third insulating film contains nitrogen and silicon.

(9) Another embodiment of the present invention is the above-described display panel in which the partition is in contact with the second insulating film, and the partition contains nitrogen and silicon.

(10) Another embodiment of the present invention is the above-described display panel which includes an insulating layer, and in which the insulating layer fills the first gap, and the insulating layer fills a space between the first unit and the second unit.

Thus, a phenomenon in which impurities diffuse into the first light-emitting device and the second light-emitting device can be inhibited. In addition, the reliability of the first light-emitting device and the second light-emitting device can be improved. As a result, a novel display panel that is highly convenient, useful, or reliable can be provided.

(11) Another embodiment of the present invention is the above-described display panel including a first coloring layer and a second coloring layer. The first coloring layer overlaps with the first light-emitting device, and the second coloring layer overlaps with the second light-emitting device.

The second coloring layer includes a third gap between the second coloring layer and the first coloring layer, and the second coloring layer includes a first sidewall on the first coloring layer side.

The fourth unit includes a second sidewall continuous with the first sidewall, and the second unit includes a third sidewall continuous with the second sidewall.

Thus, light emitted from the second light-emitting device can be efficiently led to the second coloring layer. As a result, a novel display panel that is highly convenient, useful, or reliable can be provided.

(12) Another embodiment of the present invention is the above-described display panel including a functional layer, a first pixel, and a second pixel.

The first pixel includes the first light-emitting device and a pixel circuit. In addition, the second pixel includes the second light-emitting device.

The functional layer includes the pixel circuit and a region having a light-transmitting property, the pixel circuit is electrically connected to the first light-emitting device, and the region having the light-transmitting property transmits light emitted from the first light-emitting device.

(13) Another embodiment of the present invention is a data processing device including one or more of a keyboard, a hardware button, a pointing device, a touch sensor, an illuminance sensor, an imaging device, an audio input device, an eye-gaze input device, and an attitude detection device and the above-described display panel.

Thus, an arithmetic device can generate the image data or the control data on the basis of the data supplied using a variety of input devices. Thus, a novel data processing device that is highly convenient or reliable can be provided.

(14) Another embodiment of the present invention is a method for manufacturing a display panel including a first step to a tenth step.

In the first step, a first electrode and a second electrode are formed.

In the second step, a partition is formed between the first electrode and the second electrode.

In the third step, a first layer is formed over the first electrode and the second electrode.

In the fourth step, a first unit is formed over the first layer.

In the fifth step, a third electrode is formed over the first unit.

In the sixth step, the first layer, the first unit, and the third electrode over the second electrode are removed by a photoetching method to form a first light-emitting device.

In the seventh step, a second layer is formed over the third electrode and the second electrode.

In the eighth step, a second unit is formed over the second layer.

In the ninth step, a fourth electrode is formed over the second unit.

In the tenth step, the second layer, the second unit, and the fourth electrode over the third electrode are removed by a photoetching method to form a second light-emitting device separated from the first light-emitting device.

(15) Another embodiment of the present invention is a method for manufacturing a display panel including a first step to an eighth step.

In the first step, a first electrode and a second electrode are formed.

In the second step, a partition is formed between the first electrode and the second electrode.

In the third step, a layer is formed over the first electrode and the second electrode.

In the fourth step, a first unit is formed over the layer.

In the fifth step, an intermediate layer is formed over the first unit.

In the sixth step, a second unit is formed over the intermediate layer.

In the seventh step, a conductive film is formed over the second unit.

In the eighth step, the layer, the first unit, the intermediate layer, the second unit, and the conductive film over the partition is removed by a photoetching method to form a first light-emitting device and a second light-emitting device.

Thus, the display panel including a plurality of light-emitting devices can be manufactured without using a metal mask. As a result, a method for manufacturing a novel display panel that is highly convenient, useful, or reliable can be provided.

Although a block diagram in which components are classified by their functions and shown as independent blocks is shown in the drawing attached to this specification, it is difficult to completely separate actual components according to their functions and one component can relate to a plurality of functions.

In this specification, the names of a source and a drain of a transistor interchange with each other depending on the polarity of the transistor and the levels of potentials applied to the terminals. In general, in an n-channel transistor, a terminal to which a lower potential is applied is called a source, and a terminal to which a higher potential is applied is called a drain. In a p-channel transistor, a terminal to which a lower potential is applied is called a drain, and a terminal to which a higher potential is applied is called a source. In this specification, for the sake of convenience, the connection relationship of a transistor is sometimes described assuming that the source and the drain are fixed; in reality, the names of the source and the drain interchange with each other according to the above relationship of the potentials.

In this specification, a source of a transistor means a source region that is part of a semiconductor film functioning as an active layer or a source electrode connected to the semiconductor film. Similarly, a drain of a transistor means a drain region that is part of the semiconductor film or a drain electrode connected to the semiconductor film. Moreover, a gate means a gate electrode.

In this specification, a state in which transistors are connected in series means, for example, a state in which only one of a source and a drain of a first transistor is connected to only one of a source and a drain of a second transistor. In addition, a state in which transistors are connected in parallel means a state in which one of a source and a drain of a first transistor is connected to one of a source and a drain of a second transistor and the other of the source and the drain of the first transistor is connected to the other of the source and the drain of the second transistor.

In this specification, connection means electrical connection and corresponds to a state in which a current, a voltage, or a potential can be supplied or transmitted. Accordingly, a state of being connected does not necessarily mean a state of being directly connected and also includes, in its category, a state of being indirectly connected through a circuit element such as a wiring, a resistor, a diode, or a transistor that allows a current, a voltage, or a potential to be supplied or transmitted.

In this specification, even when independent components are connected to each other in a circuit diagram, there is actually a case where one conductive film has functions of a plurality of components, such as a case where part of a wiring functions as an electrode, for example. Connection in this specification also includes such a case where one conductive film has functions of a plurality of components, in its category.

Furthermore, in this specification, one of a first electrode and a second electrode of a transistor refers to a source electrode and the other refers to a drain electrode.

### Effect of the Invention

According to one embodiment of the present invention, a novel display panel that is highly convenient, useful, or reliable can be provided. Alternatively, a method for manufacturing a novel display panel that is highly convenient, useful, or reliable can be provided. A novel data processing device that is highly convenient, useful, or reliable can be provided. Alternatively, a novel display panel, a method for manufacturing a novel display panel, a novel data processing device, or a novel semiconductor device can be provided.

Note that the description of these effects does not preclude the existence of other effects. One embodiment of the present invention does not have to have all of these effects. Other effects will be apparent from and can be derived from the description of the specification, the drawings, the claims, and the like.

### BRIEF DESCRIPTION OF THE DRAWINGS

FIG. 1A to FIG. 1C are diagrams illustrating a structure of a display panel of an embodiment.

FIG. 2 is a circuit diagram illustrating a pixel of a display panel of an embodiment.

FIG. 3A to FIG. 3D are diagrams illustrating structures of display panels of embodiments.

FIG. 4A to FIG. 4C are diagrams illustrating a structure of a display panel of an embodiment.

FIG. 5A to FIG. 5C are diagrams illustrating a structure of a display panel of an embodiment.

FIG. 6 is a diagram illustrating a structure of a display panel of an embodiment.

FIG. 7 is a diagram illustrating part of FIG. 6.

FIG. 8A and FIG. 8B are diagrams illustrating a structure of a display panel of an embodiment.

FIG. 9A to FIG. 9C are diagrams illustrating a structure of a display panel of an embodiment.

FIG. 10A to FIG. 10C are diagrams illustrating a structure of a display panel of an embodiment.

FIG. 11 is a diagram illustrating part of FIG. 10A.

FIG. 12 is a diagram illustrating a structure of a display panel of an embodiment.

FIG. 13 is a diagram illustrating a structure of a display panel of an embodiment.

FIG. 14 is a diagram illustrating a structure of a display panel of an embodiment.

FIG. 15 is a diagram illustrating a structure of a display panel of an embodiment.

FIG. 16 is a diagram illustrating a structure of a display panel of an embodiment.

FIG. 17A and FIG. 17B are diagrams illustrating a method for manufacturing a display panel of an embodiment.

FIG. 18A to FIG. 18C are diagrams illustrating a method for manufacturing a display panel of an embodiment.

FIG. 19A to FIG. 19C are diagrams illustrating a method for manufacturing a display panel of an embodiment.

FIG. 20A to FIG. 20C are diagrams illustrating a method for manufacturing a display panel of an embodiment.

FIG. 21A to FIG. 21C are diagrams illustrating a method for manufacturing a display panel of an embodiment.

FIG. 22A to FIG. 22C are diagrams illustrating a method for manufacturing a display panel of an embodiment.

FIG. 23A and FIG. 23B are diagrams illustrating a method for manufacturing a display panel of an embodiment.

FIG. 24A and FIG. 24B are diagrams illustrating a structure of a light-emitting device of an embodiment.

FIG. 25A and FIG. 25B are diagrams illustrating structures of a light-emitting device of an embodiment.

FIG. 26A to FIG. 26E are diagrams illustrating structures of a data processing device of an embodiment.

FIG. 27A to FIG. 27E are diagrams illustrating structures of a data processing device of an embodiment.

FIG. 28A and FIG. 28B are diagrams illustrating structures of a data processing device of an embodiment.

FIG. 29 is a diagram illustrating a structure of a light-emitting device of an embodiment.

### MODE FOR CARRYING OUT THE INVENTION

A display panel of one embodiment of the present invention includes a first light-emitting device, a second light-emitting device, and a partition. The first light-emitting device includes a first electrode, a second electrode, and a first layer, and the first layer includes a region interposed between the second electrode and the first electrode. The first layer contains a first material having a hole-transport property and a first substance having an acceptor property, and the first layer has an electrical resistivity greater than or equal to 1×10² [Ω·cm] and less than or equal to 1×10⁸ [Ω·cm]. The second light-emitting device includes a third electrode, a fourth electrode, and a second layer, and the second layer includes a region interposed between the fourth electrode and the third electrode. The second layer contains the first material having the hole-transport property and the first substance having the acceptor property, and the second layer includes a first gap between the second layer and the first layer. The first gap includes a region overlapping with the partition, and the first gap prevents electrical continuity between the first layer and the second layer.

Thus, electrical continuity between the first layer and the second layer is prevented. A phenomenon in which current flows between the first electrode and the fourth electrode through the first layer and the second layer can be inhibited. A phenomenon in which current flows between the third electrode and the second electrode through the first layer and the second layer can be inhibited. In addition, occurrence of a crosstalk phenomenon between the first light-emitting device and the second light-emitting device can be inhibited. As a result, a novel display panel that is highly convenient, useful, or reliable can be provided.

Embodiments are described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and a description thereof is not repeated.

### Embodiment 1

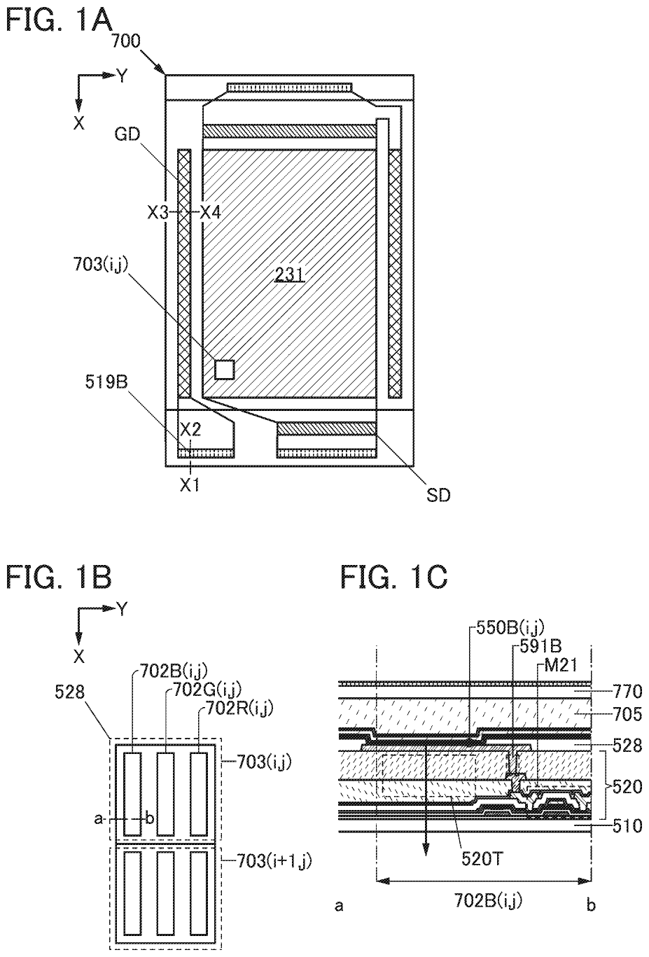

In this embodiment, a structure of a display panel of one embodiment of the present invention will be described with reference to FIG. 1 to FIG. 16.

FIG. 1 shows diagrams each illustrating the structure of the display panel of one embodiment of the present invention. FIG. 1A is a top view illustrating the display panel of one embodiment of the present invention, and FIG. 1B is a top view illustrating part of the display panel. FIG. 1C is a cross-sectional view illustrating the direction of light emitted by the display panel of one embodiment of the present invention.

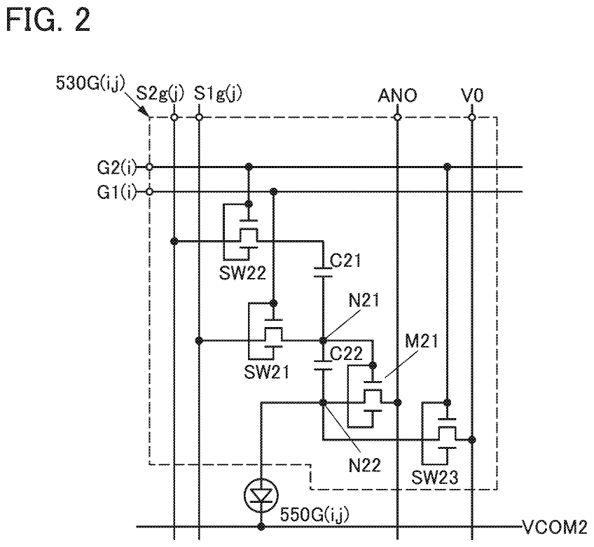

FIG. 2 is a circuit diagram illustrating a pixel of the display panel of one embodiment of the present invention.

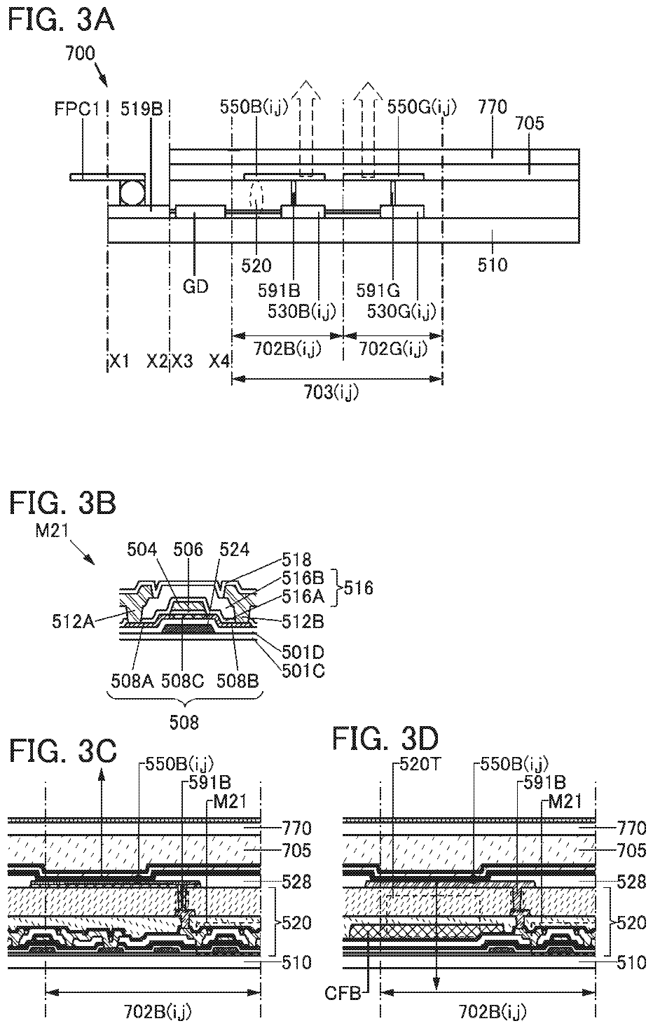

FIG. 3 shows cross-sectional views each illustrating the structure of the display panel of one embodiment of the present invention. FIG. 3A is a diagram illustrating cross sections taken along the cutting line X1-X2 and the cutting line X3-X4 in FIG. 1A and a cross section of a set of pixels 703(i,j). FIG. 3B is a cross-sectional view illustrating a transistor that can be used for the display panel of one embodiment of the present invention. FIG. 3C is a cross-sectional view illustrating the direction of light emitted by the display panel of one embodiment of the present invention, and FIG. 3D is a cross-sectional view illustrating the direction of light emitted by the display panel of one embodiment of the present invention, which is different from the display panel of one embodiment of the present invention described with reference to FIG. 3C.

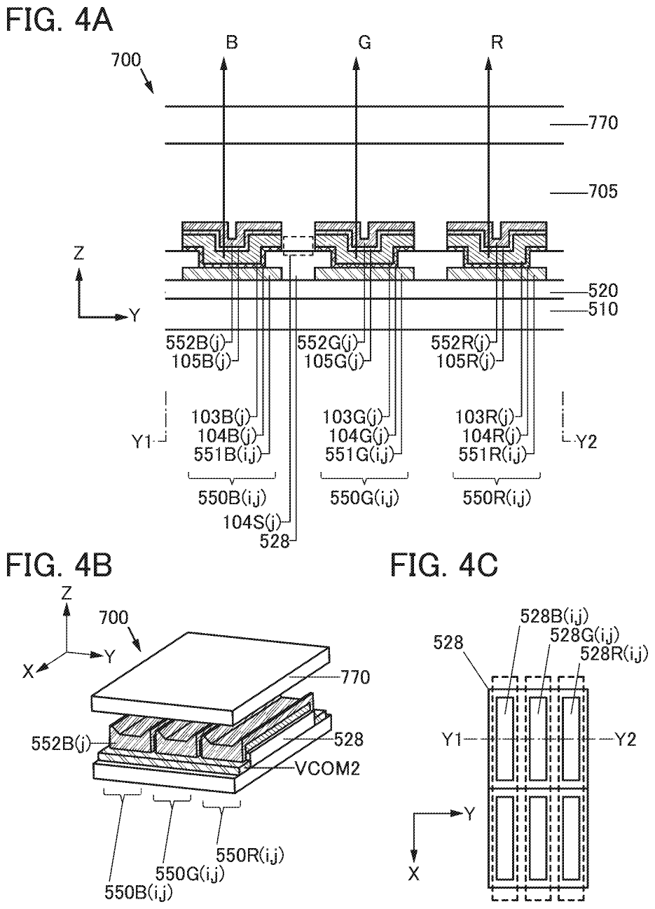

FIG. 4 shows diagrams each illustrating the structure of the display panel of one embodiment of the present invention. FIG. 4A is a cross-sectional view of a pixel in the display panel of one embodiment of the present invention, FIG. 4B is a perspective view of the pixel in FIG. 4A, and FIG. 4C is a top view of the pixel in FIG. 4A.

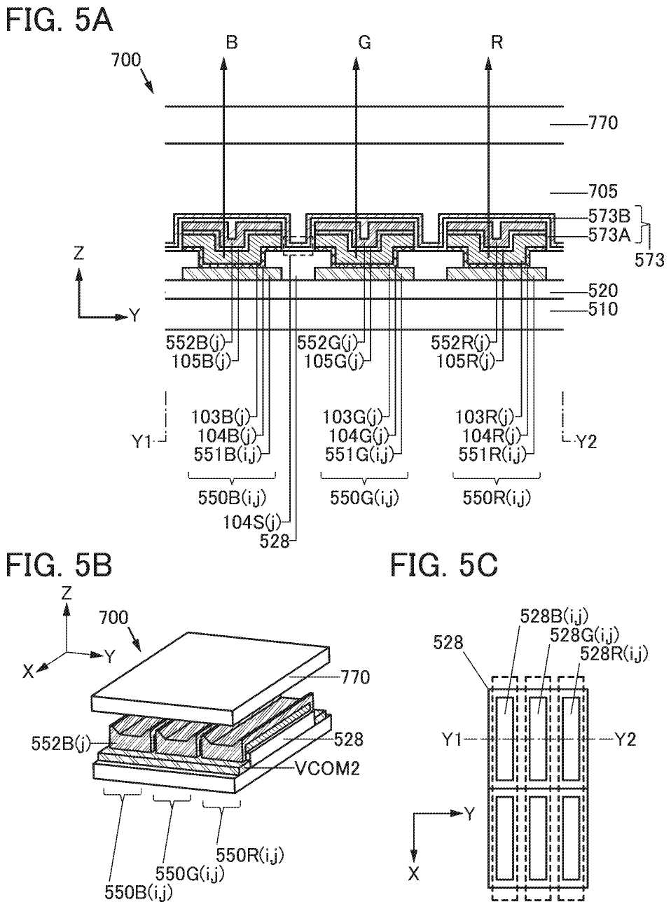

FIG. 5 shows diagrams each illustrating the structure of the display panel of one embodiment of the present invention. FIG. 5A is a cross-sectional view of a pixel in the display panel of one embodiment of the present invention, FIG. 5B is a perspective view of the pixel in FIG. 5A, and FIG. 5C is a top view of the pixel in FIG. 5A. Note that FIG. 5A is different from FIG. 4A in that an insulating film is included, and FIG. 5A and FIG. 5C are diagrams in which each of insulating films is omitted in order to avoid complexity of the drawing.

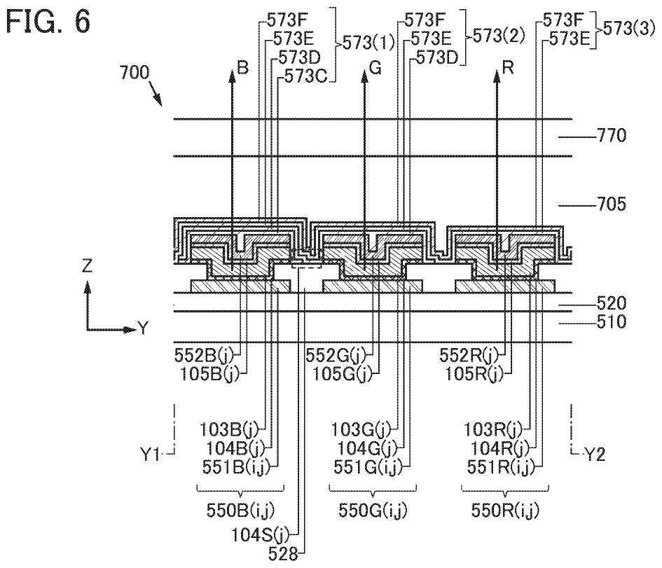

FIG. 6 is a cross-sectional view illustrating the structure of the display panel of one embodiment of the present invention.

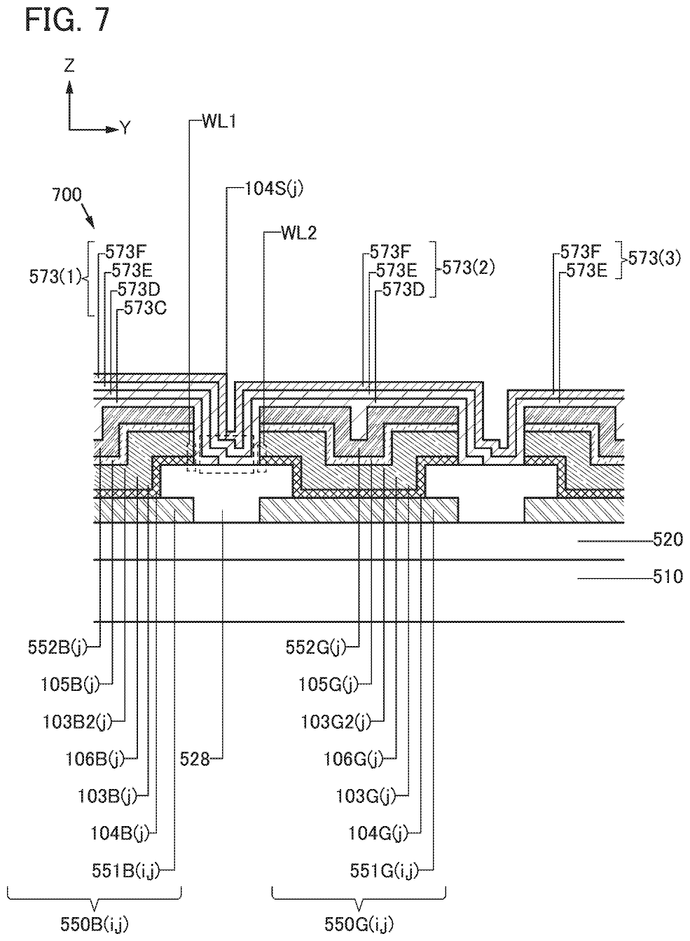

FIG. 7 is a cross-sectional view of a pixel in the display panel of one embodiment of the present invention, and FIG. 7 is a diagram illustrating part of a pixel in FIG. 6.

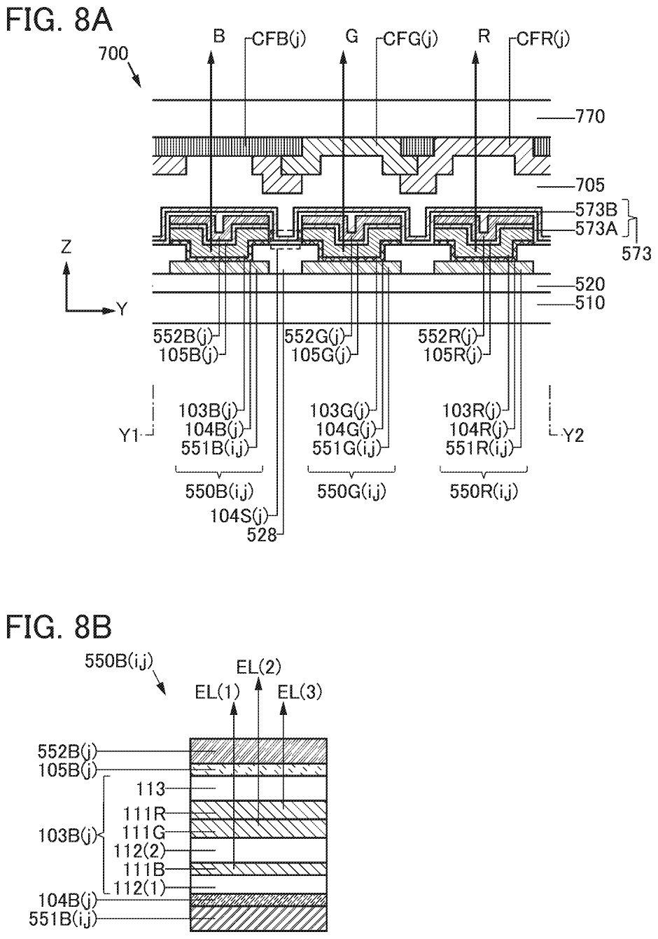

FIG. 8 shows diagrams each illustrating the structure of the display panel of one embodiment of the present invention. FIG. 8A is a cross-sectional view of a pixel in the display panel of one embodiment of the present invention, and FIG. 8B is a cross-sectional view illustrating part of the display panel in FIG. 8A.

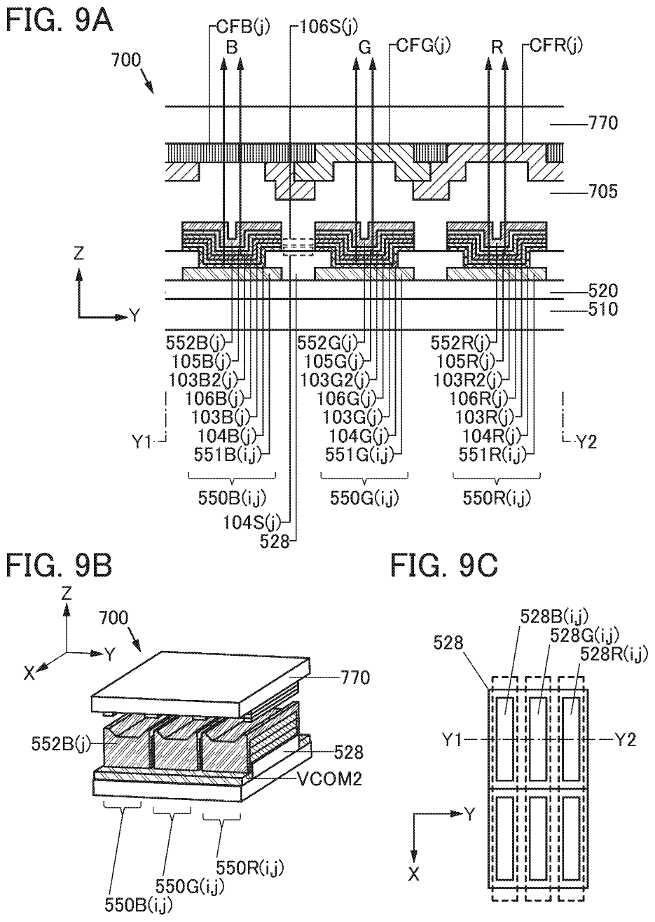

FIG. 9 shows diagrams each illustrating the structure of the display panel of one embodiment of the present invention. FIG. 9A is a cross-sectional view of a pixel in the display panel of one embodiment of the present invention, FIG. 9B is a perspective view of the pixel in FIG. 9A, and FIG. 9C is a top view of the pixel in FIG. 9A.

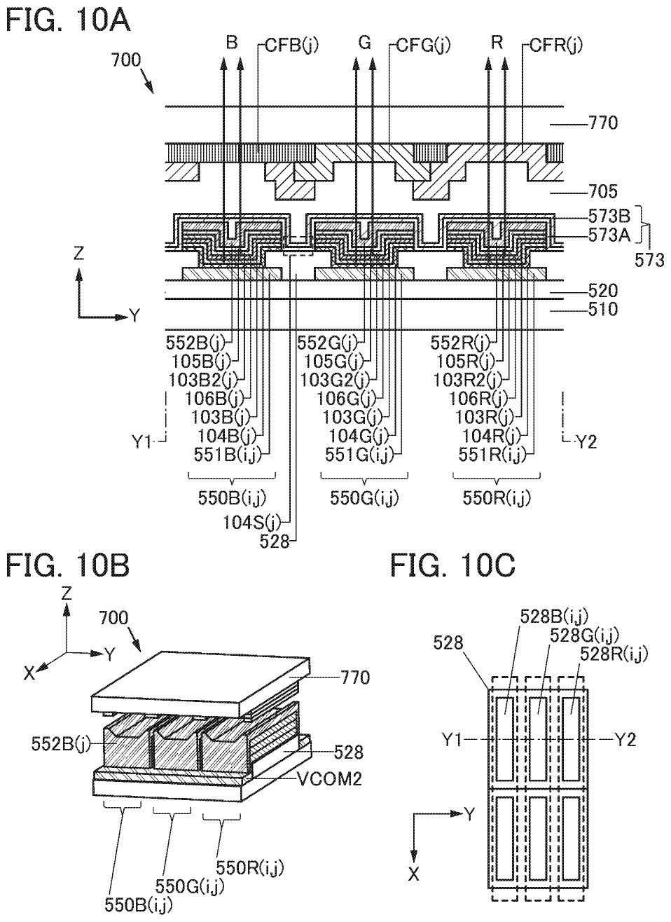

FIG. 10 shows diagrams each illustrating the structure of the display panel of one embodiment of the present invention. FIG. 10A is a cross-sectional view of a pixel in the display panel of one embodiment of the present invention, FIG. 10B is a perspective view of the pixel in FIG. 10A, and FIG. 10C is a top view of the pixel in FIG. 10A. Note that FIG. 10A is different from FIG. 9A in that an insulating film is included, and FIG. 10B and FIG. 10C are diagrams in which each of insulating films is omitted in order to avoid complexity of the drawing.

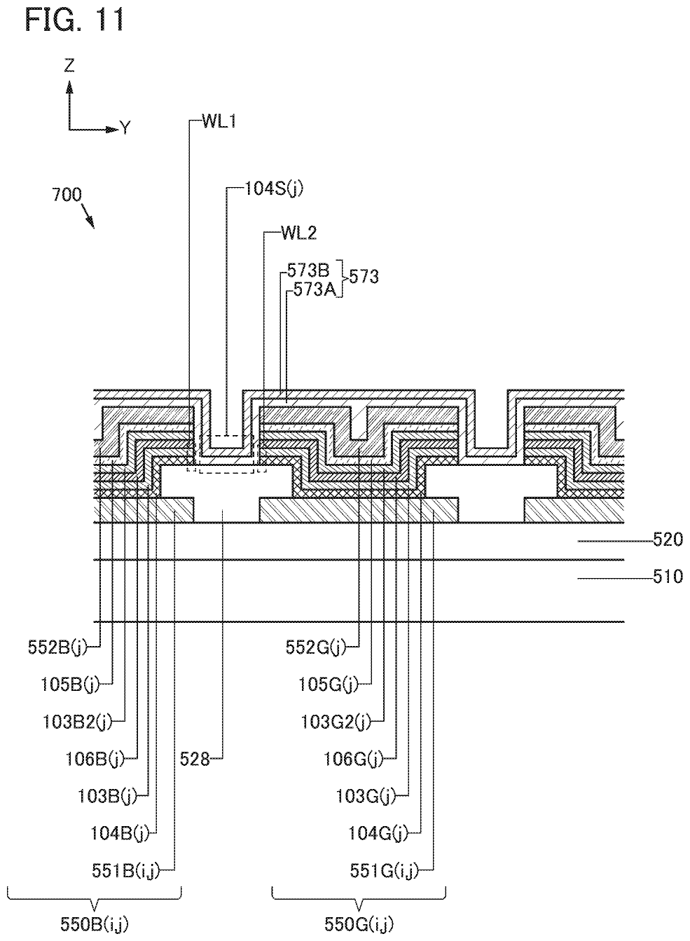

FIG. 11 is a cross-sectional view of a pixel in the display panel of one embodiment of the present invention, and illustrates part of a pixel in FIG. 10A.

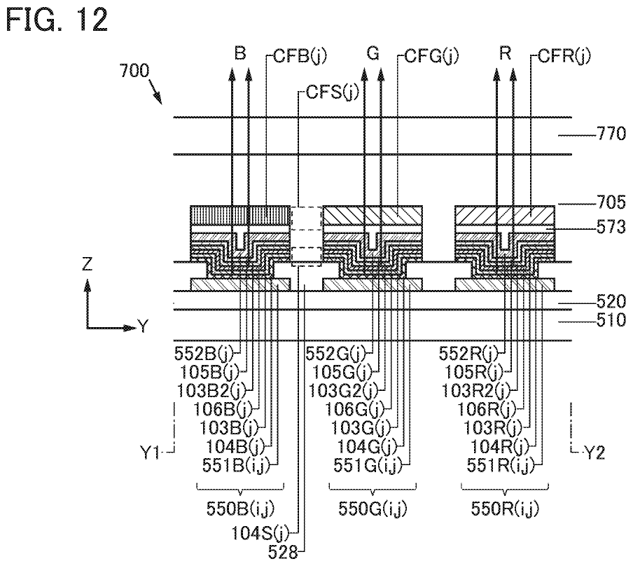

FIG. 12 is a cross-sectional view illustrating the structure of the display panel of one embodiment of the present invention.

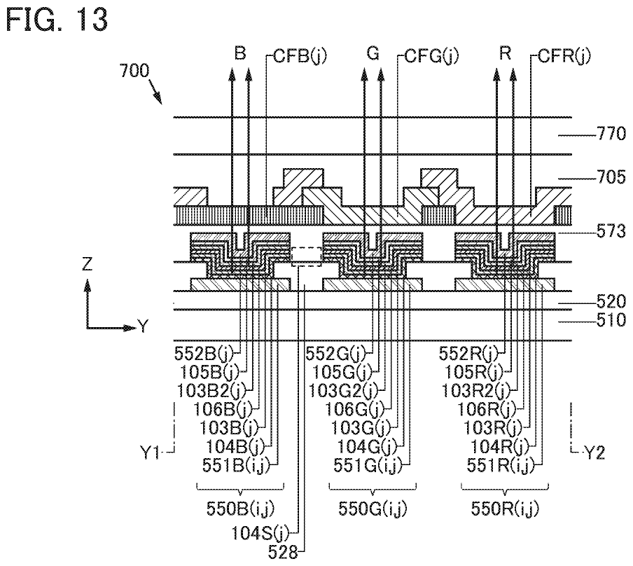

FIG. 13 is a cross-sectional view illustrating the structure of the display panel of one embodiment of the present invention.

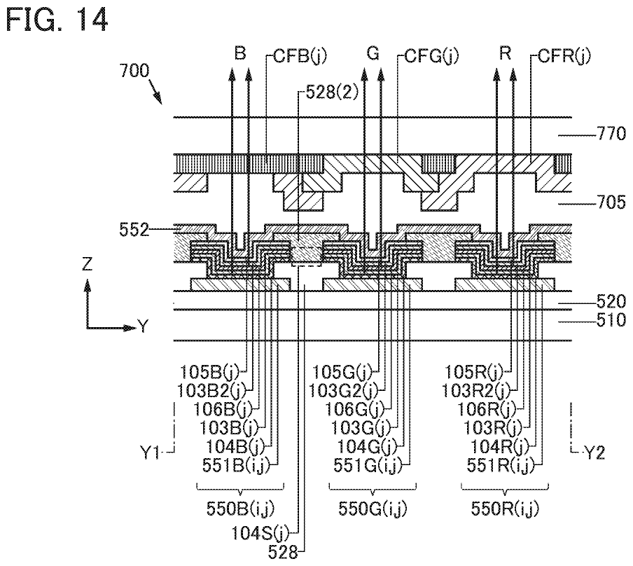

FIG. 14 is a cross-sectional view illustrating the structure of the display panel of one embodiment of the present invention.

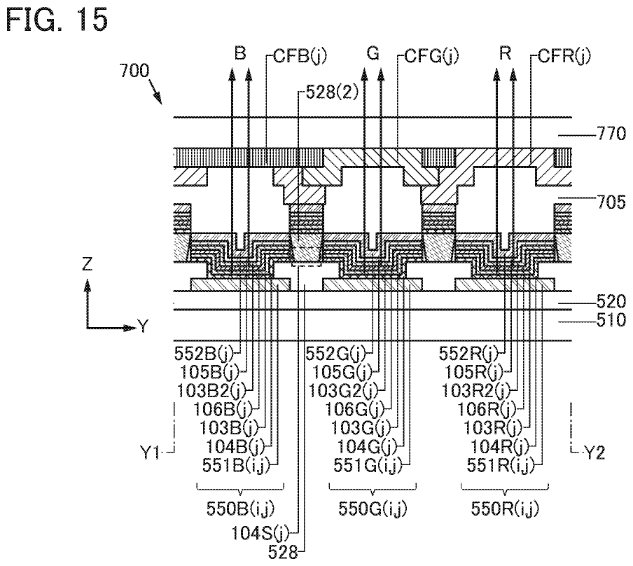

FIG. 15 is a cross-sectional view illustrating the structure of the display panel of one embodiment of the present invention.

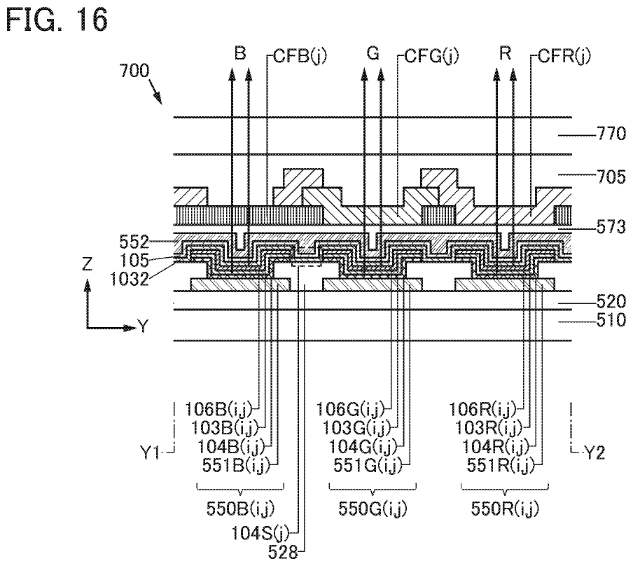

FIG. 16 is a cross-sectional view illustrating the structure of the display panel of one embodiment of the present invention.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

In this specification and the like, a structure in which light-emitting layers in light-emitting devices of different colors (here, blue (B), green (G), and red (R)) are separately formed or separately patterned may be referred to as a side-by-side (SBS) structure. In this specification and the like, a light-emitting device capable of emitting white light may be referred to as a white-light-emitting device. Note that a white light-emitting device that is combined with coloring layers (e.g., color filters) can be a light-emitting device of full-color display.

Structures of light-emitting devices can be classified roughly into a single structure and a tandem structure. A device having a single structure includes one light-emitting unit between a pair of electrodes, and the light-emitting unit preferably includes one or more light-emitting layers. To obtain white light emission, two or more kinds of light-emitting layers are selected such that their emission colors are complementary. For example, when emission color of a first light-emitting layer and emission color of a second light-emitting layer are complementary colors, a structure in which the light-emitting device emits white light as a whole can be obtained. The same applies to a light-emitting device including three or more light-emitting layers.

A device having a tandem structure includes two or more light-emitting units between a pair of electrode, and each light-emitting unit preferably includes one or more light-emitting layers. To obtain white light emission, the structure is made so that light from light-emitting layers of the light-emitting units can be combined to be white light. Note that a structure for obtaining white light emission is similar to that in the case of a single structure. In the device having the tandem structure, it is suitable that an intermediate layer such as a charge-generation layer is included between a plurality of light-emitting units.

When the white-light-emitting device (having a single structure or a tandem structure) and a light-emitting device having an SBS structure are compared to each other, the light-emitting device having an SBS structure can have lower power consumption than the white-light-emitting device. In the case of the device in which power consumption is required to be low, the light-emitting device having an SBS structure is suitably used. Meanwhile, the white-light-emitting device is suitable in terms of lower manufacturing cost or higher manufacturing yield because the manufacturing process of the white-light-emitting device is simpler than that of the light-emitting device having an SBS structure.

Note that in this specification, an integer variable of 1 or more is sometimes used in reference numerals. For example, (p) where p is an integer variable of 1 or more is sometimes used in part of a reference numeral that specifies any of p components at a maximum. As another example, (m, n) where m and n are each an integer variable of 1 or more is sometimes used in part of a reference numeral that specifies any of m×n components at a maximum.

### Structure Example 1 of Display Panel 700

A display panel 700 includes a display region 231, and the display region 231 includes the set of pixels 703(i,j) (see FIG. 1A). The display region 231 also includes a set of pixels 703(i+1,j) adjacent to the set of pixels 703(i,j) (see FIG. 1B).

### Structure Example 1 of Display Region 231

For example, the display region 231 includes 500 or more pixel sets per inch.

Furthermore, the display region 231 includes 1000 or more groups of pixel sets per inch, preferably 5000 or more groups of pixel sets per inch, further preferably 10000 or more groups of pixel sets per inch. Thus, this can reduce a screen-door effect in the case where the display panel 700 is used for a goggle-type display device, for example.

### Structure Example 2 of Display Region 231

For example, the display region 231 includes a plurality of pixels in a matrix. For example, the display region 231 includes 7600 or more pixels in the row direction and the display region 231 includes 4300 or more pixels in the column direction. Specifically, 7680 pixels are provided in the row direction and 4320 pixels are provided in the column direction.

Thus, a high-resolution image can be displayed. As a result, a novel display panel that is highly convenient or reliable can be provided.

### Structure Example 3 of Display Region 231

For example, in the case where the display panel 700 is used in a television system, the diagonal size of the display region 231 is greater than or equal to 32 inches, preferably greater than or equal to 55 inches, further preferably greater than or equal to 80 inches. The diagonal size of the display region 231 is preferably less than or equal to 200 inches, in which case the weight of the display panel 700 can be reduced.

Thus, a realistic image can be displayed. As a result, a novel display panel that is highly convenient or reliable can be provided.

### Structure Example 1 of Pixel 703(i,j)

A plurality of pixels can be used in the pixel 703(i,j) (see FIG. 1B). For example, a plurality of pixels capable of displaying colors with different hues can be used. Note that the plurality of pixels can be referred to as subpixels. A set of subpixels can be referred to as a pixel. This enables additive mixture or subtractive mixture of colors displayed by the plurality of pixels. It is possible to display a color of a hue that an individual pixel cannot display.

Specifically, a pixel 702B(i,j) displaying blue, a pixel 702G(i,j) displaying green, and a pixel 702R(i,j) displaying red can be used in the pixel 703(i,j). The pixel 702B(i,j), the pixel 702G(i,j), and the pixel 702R(i,j) can each be referred to as a subpixel.

A pixel displaying white or the like can be used in addition to the above set in the pixel 703(i,j), for example. A pixel displaying cyan, a pixel displaying magenta, and a pixel displaying yellow can be used in the pixel 703(i,j).

A pixel emitting infrared rays can be used in addition to the above set in the pixel 703(i,j), for example. Specifically, a pixel that emits light with a wavelength greater than or equal to 650 nm and less than or equal to 1000 nm can be used in the pixel 703(i,j).

### Structure Example 2 of Display Panel 700

The display panel 700 described in this embodiment includes a driver circuit GD and a driver circuit SD (see FIG. 1A and FIG. 3A). In addition, a terminal 519B is included. The terminal 519B can be electrically connected to a flexible printed circuit FPC1, for example.

### Structure Example of Driver Circuit Gd

The driver circuit GD has a function of supplying a first selection signal and a second selection signal. For example, the driver circuit GD is electrically connected to a conductive film G1(i) to supply the first selection signal, and is electrically connected to a conductive film G2(i) to supply the second selection signal.

### Structure Example of Driver Circuit Sd

The driver circuit SD has a function of supplying an image signal and a control signal, and the control signal includes a first level and a second level. For example, the driver circuit SD is electrically connected to a conductive film S1g(j) to supply the image signal, and is electrically connected to a conductive film S2g(j) to supply the control signal.

### Structure Example 3 of Display Panel 700

The display panel 700 includes the set of pixels 703(i,j) and a functional layer 520 (see FIG. 3A).

The set of pixels 703(i,j) includes the pixel 702B(i,j), the pixel 702G(i,j), and a partition 528 (see FIG. 1B).

The pixel 702B(i,j) includes a light-emitting device 550B(i,j) and a pixel circuit 530B(i,j) (see FIG. 3A).

Note that the pixel 702G(i,j) includes a light-emitting device 550G(i,j).

The display panel 700 includes a base material 510, a base material 770, and the functional layer 520 (see FIG. 3A). The functional layer 520 is interposed between the base material 770 and the base material 510. The display panel 700 includes an insulating layer 705, and the insulating layer 705 has a function of bonding the base material 770 and the functional layer 520.

The functional layer 520 includes the pixel circuit 530B(i,j), a pixel circuit 530G(i,j), and the driver circuit GD. The pixel circuit 530B(i,j) is electrically connected to the light-emitting device 550B(i,j) through an opening portion 591B, and the pixel circuit 530G(i,j) is electrically connected to the light-emitting device 550G(i,j) through an opening portion 591G.

Note that the display panel 700 displays information through the base material 770 (see FIG. 3C). In other words, the light-emitting device 550B(i,j) emits light toward the direction in which the functional layer 520 is not placed. The light-emitting device 550B(i,j) can be referred to as a top-emission light-emitting element.

Note that a base material in which touch sensors are arranged in a matrix can be used as the base material 770. For example, a capacitive touch sensor or an optical touch sensor can be used for the base material 770. Thus, the display panel of one embodiment of the present invention can be used as a touch panel.

### Structure Example 4 of Display Panel 700

The display panel 700 includes the base material 510, the base material 770, and the functional layer 520 (see FIG. 3D). Note that the display panel 700 described with reference to FIG. 3D is different from the display panel 700 described with reference to FIG. 3C in that information is displayed through the base material 510. In other words, the light-emitting device 550B(i,j) emits light toward the functional layer 520. The light-emitting device 550B(i,j) can be referred to as a bottom-emission light-emitting element.

The functional layer 520 includes the pixel circuit 530B(i,j) and a region 520T having a light-transmitting property (see FIG. 3A and FIG. 3D). The pixel circuit 530B(i,j) is electrically connected to the light-emitting device 550B(i,j), and the region 520T having a light-transmitting property transmits light emitted from the light-emitting device 550B(i,j).

### Structure Example 5 of Display Panel 700

The display panel 700 includes the conductive film G1(i), the conductive film G2(i), the conductive film S1g(j), the conductive film S2g(j), a conductive film ANO, and a conductive film VCOM2 (see FIG. 2).

For example, the conductive film G1(i) is supplied with the first selection signal, the conductive film G2(i) is supplied with the second selection signal, the conductive film S1g(j) is supplied with the image signal, and the conductive film S2g(j) is supplied with the control signal.

### Structure Example 2 of Pixel 703(i,j)

The set of pixels 703(i,j) includes the pixel 702G(i,j) (see FIG. 1B). The pixel 702G(i,j) includes the pixel circuit 530G(i,j) and the light-emitting device 550G(i,j) (see FIG. 2).

### Structure Example 1 of Pixel Circuit 530G(i,j)

The pixel circuit 530G(i,j) is supplied with the first selection signal, and the pixel circuit 530G(i,j) obtains an image signal on the basis of the first selection signal. For example, the first selection signal can be supplied using the conductive film G1(i) (see FIG. 2). The image signal can be supplied using the conductive film S1g(j). Note that the operation of supplying the first selection signal and making the pixel circuit 530G(i,j) obtain the image signal can be referred to as “writing”.

### Structure Example 2 of Pixel Circuit 530G(i,j)

The pixel circuit 530G(i,j) includes a switch SW21, a switch SW22, a transistor M21, a capacitor C21, and a node N21 (see FIG. 2). In addition, the pixel circuit 530G(i,j) includes a node N22, a capacitor C22, and a switch SW23.

The transistor M21 includes a gate electrode electrically connected to the node N21, a first electrode electrically connected to the light-emitting device 550G(i,j), and a second electrode electrically connected to the conductive film ANO.

The switch SW21 includes a first terminal electrically connected to the node N21 and a second terminal electrically connected to the conductive film S1g(j), and has a function of controlling the conduction state or the non-conduction state on the basis of a potential of the conductive film G1(i).

The switch SW22 includes a first terminal electrically connected to the conductive film S2g(j), and has a function of controlling the conduction state or the non-conduction state on the basis of a potential of the conductive film G2(i).

The capacitor C21 includes a conductive film electrically connected to the node N21 and a conductive film electrically connected to a second electrode of the switch SW22.

Thus, the image signal can be stored in the node N21. A potential of the node N21 can be changed using the switch SW22. Alternatively, the intensity of light emitted from the light-emitting device 550G(i,j) can be controlled with the potential of the node N21.

### Structure Example of Transistor M21

A bottom-gate transistor, a top-gate transistor, or the like can be used in the functional layer 520. Specifically, a transistor can be used as a switch.

The transistor M21 includes a semiconductor film 508, a conductive film 504, a conductive film 512A, and a conductive film 512B (see FIG. 3B). The transistor M21 is formed over an insulating film 501C, for example. Note that an insulating film 518 may be formed and the transistor M21 may be interposed between the insulating film 501C and the insulating film 518. Furthermore, an insulating film 516 may be formed between the insulating film 518 and the insulating film 501C, and the semiconductor film 508 may be interposed between the insulating film 516 and the insulating film 501C. For example, a film in which an insulating film 516A and an insulating film 516B are stacked can be used as the insulating film 516.

The semiconductor film 508 includes a region 508A electrically connected to the conductive film 512A and a region 508B electrically connected to the conductive film 512B. The semiconductor film 508 includes a region 508C between the region 508A and the region 508B.

The conductive film 504 includes a region overlapping with the region 508C, and the conductive film 504 has a function of a first gate electrode.

An insulating film 506 includes a region interposed between the semiconductor film 508 and the conductive film 504. The insulating film 506 has a function of a first gate insulating film.

The conductive film 512A has one of a function of a source electrode and a function of a drain electrode, and the conductive film 512B has the other of the function of the source electrode and the function of the drain electrode.

A conductive film 524 can be used for the transistor M21. The conductive film 524 includes a region where the semiconductor film 508 is interposed between the conductive film 524 and the conductive film 504. The conductive film 524 has a function of a second gate electrode. An insulating film 501D is interposed between the semiconductor film 508 and the conductive film 524, and has a function of a second gate insulating film.

Note that the semiconductor film used in the transistor of the driver circuit can be formed in the step of forming the semiconductor film used in the transistor of the pixel circuit. A semiconductor film having the same composition as the semiconductor film used in the transistor of the pixel circuit can be used in the driver circuit, for example.

### Structure Example 1 of Semiconductor Film 508

A semiconductor containing a Group 14 element can be used for the semiconductor film 508, for example. Specifically, a semiconductor containing silicon can be used for the semiconductor film 508.

### Hydrogenated Amorphous Silicon

For example, hydrogenated amorphous silicon can be used for the semiconductor film 508. Alternatively, microcrystalline silicon or the like can be used for the semiconductor film 508. Thus, a display panel having less display unevenness than a display panel using polysilicon for the semiconductor film 508 can be provided, for example. Alternatively, the size of the display panel can be easily increased.

### Polysilicon

For example, polysilicon can be used for the semiconductor film 508. In this case, the field-effect mobility of the transistor can be higher than that of a transistor using hydrogenated amorphous silicon for the semiconductor film 508, for example. The driving capability can be higher than that of the transistor using hydrogenated amorphous silicon for the semiconductor film 508, for example. The aperture ratio of the pixel can be higher than that in the case of using the transistor that uses hydrogenated amorphous silicon for the semiconductor film 508, for example.

The reliability of the transistor can be higher than that of the transistor using hydrogenated amorphous silicon for the semiconductor film 508, for example.

The temperature required for manufacture of the transistor can be lower than that required for a transistor using single crystal silicon, for example.

The semiconductor film used in the transistor of the driver circuit can be formed in the same step as the semiconductor film used in the transistor of the pixel circuit. The driver circuit can be formed over the same substrate where the pixel circuit is formed. The number of components included in an electronic device can be reduced.

### Single Crystal Silicon

For example, single crystal silicon can be used for the semiconductor film 508. In this case, for example, the resolution can be higher than that of a display panel using hydrogenated amorphous silicon for the semiconductor film 508. Alternatively, for example, a display panel having less display unevenness than the display panel using polysilicon for the semiconductor film 508 can be provided. Alternatively, smart glasses or a head-mounted display can be provided, for example.

### Structure Example 2 of Semiconductor Film 508

For example, a metal oxide can be used for the semiconductor film 508. In this case, the pixel circuit can hold an image signal for a longer time than a pixel circuit utilizing a transistor using amorphous silicon for a semiconductor film. Specifically, a selection signal can be supplied at a frequency of lower than 30 Hz, preferably lower than 1 Hz, further preferably less than once per minute with the suppressed occurrence of flickers. Consequently, fatigue accumulation in a user of a data processing device can be reduced. Moreover, power consumption for driving can be reduced.

A transistor using an oxide semiconductor can be used, for example. Specifically, an oxide semiconductor containing indium, an oxide semiconductor containing indium, gallium, and zinc, or an oxide semiconductor containing indium, gallium, zinc, and tin can be used for the semiconductor film.

A transistor having a lower leakage current in an off state than a transistor using amorphous silicon for a semiconductor film can be used, for example. Specifically, a transistor using an oxide semiconductor for a semiconductor film can be used as a switch or the like. In that case, a potential of a floating node can be held for a longer time than in a circuit in which a transistor using amorphous silicon is used as a switch.

### Structure Example 1 of Light-Emitting Device 550G(i,j)

The light-emitting device 550G(i,j) is electrically connected to the pixel circuit 530G(i,j) (see FIG. 2). The light-emitting device 550G(i,j) includes an electrode 551G(i,j) electrically connected to the pixel circuit 530G(i,j), and an electrode 552 electrically connected to the conductive film VCOM2 (see FIG. 2 and FIG. 4A). Note that the light-emitting device 550G(i,j) has a function of operating on the basis of the potential of the node N21.

For example, an organic electroluminescence element, an inorganic electroluminescence element, a light-emitting diode, a QDLED (Quantum Dot LED), or the like can be used as the light-emitting device 550G(i,j).

### Structure Example 6 of Display Panel 700

The display panel 700 described in this embodiment includes the light-emitting device 550B(i,j), the light-emitting device 550G(i,j), the partition 528, and a light-emitting device 550R(i,j) (see FIG. 4A).

### Structure Example 1 of Light-Emitting Device 550B(i,j)

The light-emitting device 550B(i,j) includes an electrode 551B(i,j), an electrode 552B(j), a unit 103B(j), and a layer 104B(j) (see FIG. 4A). In addition, a layer 105B(j) is included. Note that the layer 105B(j) can be used for an electron-injection layer, for example.

The electrode 552B(j) overlaps with the electrode 551B(i,j), and the unit 103B(j) includes a region interposed between the electrode 552B(j) and the electrode 551B(i,j). The unit 103B(j) includes a light-emitting layer and has a function of emitting light. For example, the unit 103B(j) can emit blue light.

For example, a layer selected from a hole-transport layer, an electron-transport layer, a carrier-blocking layer, and the like can be used in the unit 103B(j).

The layer 104B(j) includes a region interposed between the unit 103B(j) and the electrode 551B(i,j), and contains a material having a hole-transport property and a substance having an acceptor property. The layer 104B(j) has an electrical resistivity greater than or equal to 1×10² [Ω·cm] and less than or equal to 1×10⁸ [Ω·cm]. Note that the layer 104B(j) can be used for a hole-injection layer, for example.

### Structure Example 2 of Light-Emitting Device 550G(i,j)

The light-emitting device 550G(i,j) includes the electrode 551G(i,j), an electrode 552G(j), a unit 103G(j), and a layer 104G(j). In addition, a layer 105G(j) is included. Note that the layer 105G(j) can be used for an electron-injection layer, for example.

The electrode 552G(j) overlaps with the electrode 551G(i,j), and the unit 103G(j) includes a region interposed between the electrode 552G(j) and the electrode 551G(i,j). The unit 103G(j) includes a light-emitting layer and has a function of emitting light. For example, the unit 103G(j) can emit green light.

For example, a layer selected from a hole-transport layer, an electron-transport layer, a carrier-blocking layer, and the like can be used in the unit 103G(j).

The layer 104G(j) includes a region interposed between the unit 103G(j) and the electrode 551G(i,j), and the layer 104G(j) contains the same material having a hole-transport property and the same substance having an acceptor property as the layer 104B(j). Note that the layer 104G(j) can be used for a hole-injection layer, for example.

The layer 104G(j) includes a gap 104S(j) between the layer 104G(j) and the layer 104B(j). Note that the layer 104B(j) and the layer 104G(j) have conductivity, and the gap 104S(j) has a function of inhibiting electrical continuity between the layer 104B(j) and the layer 104G(j).

### Structure Example 1 of Layer 104B(j) and Layer 104G(j)

The material having a hole-transport property and the substance having an acceptor property can be used for the layer 104B(j) and the layer 104G(j).

### Hole-Transport Material

For example, an aromatic amine compound or an organic compound having a π-electron rich heteroaromatic ring can be used as the material having a hole-transport property.

Thus, holes can be supplied from the anode side to the cathode side. Note that the layer 104G(j) in the light-emitting device 550G(i,j) is separated from the layer 104B(j) in the light-emitting device 550B(i,j), which can inhibit occurrence of a crosstalk phenomenon. As a result, a novel display panel that is highly convenient, useful, or reliable can be provided.

As the material having a hole-transport property in the composite material, for example, a compound having an aromatic amine skeleton, a carbazole derivative, an aromatic hydrocarbon, an aromatic hydrocarbon having a vinyl group, a high molecular compound (such as an oligomer, a dendrimer, or a polymer), or the like can be used. A material having a hole mobility of 1×10⁻⁶ cm²/Vs or higher can be suitably used as the material having a hole-transport property.

As the compound having an aromatic amine skeleton, for example, N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis{4-[bis(3-methylphenyl)amino]phenyl}-N,N′-diphenyl-(1,1′-biphenyl)-4,4′-diamine (abbreviation: DNTPD), 1,3,5-tris[N-(4-diphenylaminophenyl)-N-phenylamino]benzene (abbreviation: DPA3B), or the like can be used.

As the carbazole derivative, for example, 3[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), 1,4-bis[4-(N-carbazolyl)phenyl]-2,3,5,6-tetraphenylbenzene, or the like can be used. As the aromatic hydrocarbon, for example, 2-tert-butyl-9,10-di(2-naphthyl)anthracene (abbreviation: t-BuDNA), 2-tert-butyl-9,10-di(1-naphthyl)anthrac ene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10, 10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, coronene, or the like can be used.

As the aromatic hydrocarbon having a vinyl group, for example, 4,4′-bis(2,2-diphenylvinyl)biphenyl (abbreviation: DPVBi), 9,10-bis[4-(2,2-diphenylvinyl)phenyl]anthracene (abbreviation: DPVPA), or the like can be used.

As the high molecular compound, for example, poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N-phenylamino}phenyl)methacrylamide] (abbreviation: PTPDMA), poly[N,N′-bis(4-butylphenyl)-N,N′-bis(phenyl)benzidine] (abbreviation: Poly-TPD), or the like can be used.

Furthermore, a substance having any of a carbazole skeleton, a dibenzofuran skeleton, a dibenzothiophene skeleton, and an anthracene skeleton can be suitably used as the material having a hole-transport property in the composite material, for example. Moreover, as the material having a hole-transport property in the composite material, it is possible to use a substance including any of an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group. With the use of a substance including an N,N-bis(4-biphenyl)amino group, the reliability of the light-emitting device can be increased.

As these materials, for example, N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N′-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBA(3NB), 4-[4-(2-naphthyl)phenyl]-4′,4″-diphenyltriphenylamine (abbreviation: BBA(3NBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-diphenyl-4′-(2-naphthyl)-4″-{9-(4-biphenylyl)carbazole)}triphenylamine (abbreviation: YGTBiβNB), N-[4-(9-phenyl-9H-carbazol-3-yl)phenyl]-N-[4-(1-naphthyl)phenyl]-9,9′-spirobi(9H-fluoren)-2-amine (abbreviation: PCBNBSF), N,N-bis(4-biphenylyl)-9,9′-spirobi[9H-fluoren]-2-amine (abbreviation: BBASF), N,N-bis(1,1′-biphenyl-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi(9H-fluoren)-4-amine (abbreviation: oFBiSF), N-(4-biphenyl)-N-(dibenzofuran-4-yl)-9,9-dimethyl-9H-fluoren-2-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]spiro-9,9′-bifluoren-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N′-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine, or the like can be used.

### Substance Having Acceptor Property

For example, an organic compound containing fluorine or a cyano group or a transition metal oxide can be used for the substance having an acceptor property. The substance having an acceptor property can extract electrons from an adjacent hole-transport layer or an adjacent material having a hole-transport property by the application of an electric field. Note that an organic compound having an acceptor property is easily evaporated and deposited. As a result, the productivity of the light-emitting device can be increased.

Specifically, it is possible to use, for example, 7,7,8,8-tetracyano-2,3,5,6-tetrafluoroquinodim ethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodim ethane (abbreviation: F6-TCNNQ), 2-(7-dicyanomethylen-1,3,4,5,6,8,9,10-octafluoro-7H-pyren-2-ylidene)malononitrile, or the like can be used.

A compound in which electron-withdrawing groups are bonded to a condensed aromatic ring having a plurality of heteroatoms, such as HAT-CN, is particularly preferable because it is thermally stable.

Alternatively, a [3]radialene derivative having an electron-withdrawing group (in particular, a halogen group or a cyano group such as a fluoro group) is preferable because it has a very high electron-accepting property.

Specifically, it is possible to use, for example, α,α′α″, -1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], or α,α′,α″-1,2,3-cyclopropanetriylidenetris[2,3,4,5,6-pentafluorobenzeneacetonitrile].

As the substance having an acceptor property, molybdenum oxide, vanadium oxide, ruthenium oxide, tungsten oxide, manganese oxide, or the like can be used.

Alternatively, it is possible to use phthalocyanine (abbreviation: H₂Pc), a phthalocyanine-based complex compound such as copper phthalocyanine (CuPc), and compounds having an aromatic amine skeleton, such as 4,4′-bis[N-(4-diphenylaminophenyl)-N-phenylamino]biphenyl (abbreviation: DPAB) and N,N′-bis{4-[bis(3-methylphenyl)amino]phenyl}-N,N′-diphenyl-(1,1′-biphenyl)-4,4′-diamine (abbreviation: DNTPD).

Alternatively, a high molecular compound such as poly(3,4-ethylenedioxythiophene)/poly(styrenesulfonic acid) (PEDOT/PSS), or the like can be used.

### Structure Example 1 of Partition 528

The partition 528 includes an opening portion 528B(i,j) and an opening portion 528G(i,j) (see FIG. 4C). The opening portion 528B(i,j) overlaps with the electrode 551B(i,j), and the opening portion 528G(i,j) overlaps with the electrode 551G(i,j). The partition 528 further includes an opening portion 528R(i,j).

The partition 528 overlaps with the gap 1045(j) between the opening portion 528B(i,j) and the opening portion 528G(i,j) (see FIG. 4A).

An inorganic material, an organic material, a composite material of an inorganic material and an organic material, or the like can be used for the partition 528. Specifically, an inorganic oxide film, an inorganic nitride film, an inorganic oxynitride film, or the like, or a stacked-layer material in which a plurality of films selected from these films are stacked can be used as the partition 528. For example, a silicon oxide film, a film containing an acrylic resin, a film containing polyimide, or the like can be used as the partition 528.

Thus, a phenomenon in which current flows between the electrode 551B(i,j) and the electrode 552G(j) through the layer 104B(j) and the layer 104G(j) can be inhibited. A phenomenon in which current flows between the electrode 551G(i,j) and the electrode 552B(j) through the layer 104B(j) and the layer 104G(j) can be inhibited. In addition, occurrence of a crosstalk phenomenon between the light-emitting device 550B(i,j) and the light-emitting device 550G(i,j) can be inhibited.

For example, on a high-resolution display panel exceeding 1000 ppi, a crosstalk phenomenon occurs when there is electrical continuity between the layer 104B(j) and the layer 104G(j), which narrows the color gamut displayable on the display panel. Providing a gap 104S in a display panel with a high resolution exceeding 1000 ppi, preferably in a display panel with a high resolution exceeding 2000 ppi, or further preferably in a display panel with an ultrahigh resolution exceeding 5000 ppi enables the display panel to exhibit bright colors.

### Structure Example of Light-Emitting Device 550R(i,j)

The light-emitting device 550R(i,j) includes an electrode 551R(i,j), an electrode 552R(j), a unit 103R(j), and a layer 104R(j). The unit 103R(j) has a function of emitting light. For example, the unit 103R(j) can emit red light. The layer 104R(j) can be used for a hole-injection layer, for example. In addition, the layer 104R(j) includes a layer 105R(j), and the layer 105R(j) can be used for an electron-injection layer, for example.

For example, a blue light-emitting material can be used for the unit 103B(j), a green light-emitting material can be used for the unit 103G(j), and a red light-emitting material can be used for the unit 103R(j). Thus, the emission efficiency of each of the light-emitting devices can be increased. In addition, light emitted from each of the light-emitting devices can be efficiently utilized.

### Structure Example 7 of Display Panel 700

The display panel 700 described in this embodiment includes the insulating layer 705 (see FIG. 4A).

### Structure Example of Insulating Layer 705

The insulating layer 705 fills the gap 104S(j) and fills a space between the unit 103B(j) and the unit 103G(j).

The insulating layer 705 includes a region interposed between the functional layer 520 and the base material 770 and has a function of bonding the functional layer 520 and the base material 770 together.

An inorganic material, an organic material, a composite material of an inorganic material and an organic material, or the like can be used for the insulating layer 705.

Specifically, an inorganic oxide film, an inorganic nitride film, an inorganic oxynitride film, or the like, or a stacked-layer material in which a plurality of films selected from these films are stacked can be used as the insulating layer 705.

For example, a film including a silicon oxide film, a silicon nitride film, a silicon oxynitride film, an aluminum oxide film, or the like, or a film including a stacked-layer material in which a plurality of films selected from these films are stacked can be used as the insulating layer 705. Note that the silicon nitride film is a dense film and has an excellent function of inhibiting diffusion of impurities. Alternatively, an oxide semiconductor (e.g., IGZO film) may be used as the insulating layer 705. Specifically, a stacked-layer structure of an aluminum oxide film and an IGZO film over the aluminum oxide film, or the like can be used.

For example, polyester, polyolefin, polyamide, polyimide, polycarbonate, polysiloxane, an acrylic resin, or the like, or a stacked-layer material, a composite material, or the like of a plurality of resins selected from these resins can be used for the insulating layer 705.

For example, an organic material such as a reactive curable adhesive, a photocurable adhesive, a thermosetting adhesive, or/and an anaerobic adhesive can be used for the insulating layer 705.

Thus, a phenomenon in which impurities diffuse into the light-emitting device 550B(i,j) and the light-emitting device 550G(i,j) can be inhibited. The reliability of the light-emitting device 550B(i,j) and the light-emitting device 550G(i,j) can be increased. As a result, a novel display panel that is highly convenient, useful, or reliable can be provided.

### Structure Example 8 of Display Panel 700

The structure of the display panel of one embodiment of the present invention is described with reference to FIG. 5.

Note that the display panel 700 described with reference to FIG. 5 is different from the display panel 700 described with reference to FIG. 4 in that an insulating film 573 is included.

### Structure Example 1 of Insulating Film 573

The electrode 552B(j) is interposed between the insulating film 573 and the electrode 551B(i,j), and the electrode 552G(j) is interposed between the insulating film 573 and the electrode 551G(i,j) (see FIG. 5A).

For example, aluminum oxide, magnesium oxide, hafnium oxide, gallium oxide, indium gallium zinc oxide, silicon nitride, silicon nitride oxide, or the like can be used for the insulating film 573.

Thus, diffusion of impurities existing around the light-emitting device 550B(i,j) into the light-emitting device 550B(i,j) can be inhibited. In addition, diffusion of impurities existing around the light-emitting device 550G(i,j) into the light-emitting device 550G(i,j) can be inhibited. As a result, a novel display panel that is highly convenient, useful, or reliable can be provided.

### Structure Example of Insulating Film 573A

For example, an oxide having an amorphous structure can be used for an insulating film 573A. Specifically, a metal oxide such as aluminum oxide (AlOₓ: x is a given number greater than 0) or magnesium oxide (MgO_{y}: y is a given number greater than 0) can be suitably used. In the case where aluminum oxide is used for the insulating film 573A, the insulating film 573A contains at least oxygen and aluminum.

In a metal oxide having an amorphous structure, an oxygen atom has a dangling bond and sometimes has a property of capturing or fixing hydrogen or a molecule containing hydrogen with the dangling bond. Thus, water or water existing around the light-emitting device 550G(i,j) can be captured or fixed.

Although the insulating film 573A preferably has an amorphous structure, a crystal region may be partly formed. The insulating film 573A may have a multilayer structure in which a layer having an amorphous structure and a layer having a crystal region are stacked. For example, the insulating film 573A may have a stacked-layer structure where a layer including a crystal region, typically, a layer having a polycrystalline structure is provided over the layer having an amorphous structure.

A stacked film in which a plurality of layers are stacked can be used as the insulating film 573A. For example, a stacked film in which aluminum oxide deposited by an atomic layer deposition (ALD) method and aluminum oxide deposited by a sputtering method can be used as the insulating film 573A. Thus, in the case where a pin hole, disconnection, or the like is formed in the film deposited by a sputtering method, a portion overlapping with the pin hole, the disconnection, or the like can be filled in by using the film deposited by an ALD method with favorable coverage.

### Method for Forming Insulating Film 573A

The insulating film 573A can be formed by a sputtering method, a chemical vapor deposition (CVD) method, a molecular beam epitaxy (MBE) method, a pulsed laser deposition (PLD) method, an ALD method, or the like. The insulating film 573A can have a predetermined shape by a lithography method or the like.

For example, aluminum oxide can be deposited by using an aluminum target in an atmosphere containing an oxygen gas or using a pulsed DC sputtering method. Thus, the insulating film 573A can be formed by a sputtering method without using a gas containing a hydrogen molecule as a deposition gas. This can reduce the hydrogen concentration in the insulating film 573A. Furthermore, more impurities such as water included in the light-emitting device 550G(i,j) can be captured or fixed.

### Structure Example of Insulating Film 573B

For example, silicon nitride (SiNₓ: x is a given number greater than 0) can be suitably used. In this case, an insulating film 573B is an insulating film containing at least nitrogen and silicon. Silicon nitride has high capability of inhibiting diffusion of impurities such as water.

A stacked film in which a plurality of layers are stacked can be used as the insulating film 573B. For example, a stacked film in which silicon nitride deposited by a sputtering method and silicon nitride deposited by a plasma enhanced ALD (PEALD) method are stacked can be used for the insulating film 573B. Thus, in the case where a pin hole, disconnection, or the like is formed in the film deposited by a sputtering method, a portion overlapping with the pin hole, the disconnection, or the like can be filled in by using the film deposited by an ALD method with favorable coverage.

Heat treatment can be performed after the deposition of the insulating film 573B. Thus, water contained in the light-emitting device 550G(i,j) can be released and diffused from the light-emitting device 550G(i,j) to the insulating film 573A. The concentration of water contained in the light-emitting device 550G(i,j) can be reduced. The insulating film 573B can inhibit diffusion of water from the outside of the insulating film 573B to the light-emitting device 550G(i,j).

### Structure Example 2 of Partition 528

The partition 528 is in contact with the insulating film 573A and the partition 528 contains silicon nitride.

An insulating film which has a high capability of inhibiting diffusion of impurities such as water can be used for the partition 528. For example, a structure similar to that of the insulating film 573B can be suitably used. The partition 528 is in contact with the insulating film 573A in a region not overlapping with the light-emitting device 550G(i,j). In other words, the light-emitting device 550G(i,j) can be sealed by the insulating film 573A, the insulating film 573B, and the partition 528.

Thus, a phenomenon in which water is diffused from the outside of the insulating film 573B and the partition 528 into the light-emitting device 550G(i,j) can be inhibited. Furthermore, water in the insulating film 573B and the partition 528 can be captured or fixed. The concentration of water in the light-emitting device 550G(i,j) can be reduced. As a result, a novel display panel that is highly convenient, useful, or reliable can be provided.

### Structure Example 2 of Insulating Film 573

In addition, an insulating film 573(1), an insulating film 573(2), and an insulating film 573(3) can be used for the insulating film 573 (see FIG. 6 and FIG. 7).

The insulating film 573(1) includes an insulating film 573C, an insulating film 573D, an insulating film 573E, and an insulating film 573F. The insulating film 573C is in contact with a sidewall WL1 of the layer 104B(j) and the partition 528. The insulating film 573C is interposed between the insulating film 573D and the electrode 552B(j).

The insulating film 573(2) includes the insulating film 573D, the insulating film 573E, and the insulating film 573F. The insulating film 573D is in contact with a sidewall WL2 of the layer 104G(j) and the partition 528. The insulating film 573D is interposed between the insulating film 573E and the electrode 552G(j).

The insulating film 573(3) includes the insulating film 573E and the insulating film 573F. The insulating film 573E is in contact with a sidewall of the layer 104R(j) and the partition 528. The insulating film 573E is interposed between the insulating film 573F and the electrode 552R(j). The insulating film 573F covers the insulating film 573E.

Thus, for example, after the formation of the light-emitting device 550B(i,j), the insulating film 573C is formed, and then, the light-emitting device 550G(i,j) can be formed. Alternatively, the insulating film 573D is formed after the formation of the light-emitting device 550G(i,j), and then, the light-emitting device 550R(i,j) can be formed. In the step of forming the light-emitting device 550G(i,j), the light-emitting device 550B(i,j) can be protected using the insulating film 573C. Furthermore, in the step of forming the light-emitting device 550R(i,j), the light-emitting device 550G(i,j) can be protected using the insulating film 573D. By using the insulating film 573(3), the light-emitting device 550B(i,j), the light-emitting device 550G(i,j), and the light-emitting device 550R(i,j) can be protected. As a result, a novel display panel that is highly convenient, useful, or reliable can be provided.

### Structure Example 9 of Display Panel 700

The structure of the display panel of one embodiment of the present invention is described with reference to FIG. 8.

Note that the display panel 700 described with reference to FIG. 8 is different from the display panel 700 described with reference to FIG. 5 in that the light-emitting device 550B(i,j), the light-emitting device 550G(i,j), and the light-emitting device 550R(i,j) all emit white light.

In addition, the display panel 700 described with reference to FIG. 8 is different from the display panel 700 described with reference to FIG. 5 in that a coloring layer CFB(j), a coloring layer CFG(j), and a coloring layer CFR(j) are included (see FIG. 8A). Different portions will be described in detail here, and the above description is referred to for portions that can use similar structures.

### Structure Example 1 of Unit 103B(j)

For example, a layer 111B emitting blue light EL(1), a layer 111G emitting green light EL(2), and a layer 111R emitting red light EL(3) can be used for one unit 103B(j) (see FIG. 8B). Thus, white light can be emitted.

Specifically, a stacked structure of the layer 111B containing a blue light-emitting material, the layer 111G containing a green light-emitting material, and the layer 111R containing a red light-emitting material can be used for the unit 103B(j) (see FIG. 8B).

A layer containing a hole-transport material, a layer containing an electron-transport material, and a layer containing a bipolar material can be used for the unit 103B(j). For example, the hole-transport material can be used for a layer 112(1). The electron-transport material can be used for a layer 113. The bipolar material can be used for a layer 112(2).

Note that the structure used for the unit 103B(j) can be used for the unit 103G(j) and the unit 103R(j).

### Structure Example 1 of Coloring Layer

The coloring layer CFB(j) overlaps with the light-emitting device 550B(i,j), the coloring layer CFG(j) overlaps with the light-emitting device 550G(i,j), and the coloring layer CFG(j) transmits light of a color different from a color of light that the coloring layer CFB(j) transmits. The coloring layer CFR(j) overlaps with the light-emitting device 550R(i,j), and the coloring layer CFR(j) transmits light of a color different from colors of light that the coloring layer CFB(j) and the coloring layer CFG(j) transmit.

For example, a material that preferentially transmits blue light can be used for the coloring layer CFB(j). Thus, blue light can be extracted from white light.

For example, a material that preferentially transmits green light can be used for the coloring layer CFG(j). Thus, green light can be extracted from white light.

For example, a material that preferentially transmits red light can be used for the coloring layer CFR(j). Thus, red light can be extracted from white light.

### Structure Example 2 of Unit 103B(j)

For example, a blue light-emitting material can be used for the unit 103B(j), the unit 103G(j), and the unit 103R(j). Thus, the light-emitting device 550B(i,j), the light-emitting device 550G(i,j), and the light-emitting device 550R(i,j) can emit blue light.

Instead of the coloring layer, a color conversion layer can be used. For example, nanoparticles, quantum dots, or the like can be used for the color conversion layer.

For example, instead of the coloring layer CFG(j), a color conversion layer which converts blue light to green light can be used. Accordingly, blue light emitted from the light-emitting device 550G(i,j) can be converted to green light. Instead of the coloring layer CFR(j), a color conversion layer which converts blue light to red light can be used. Thus, blue light emitted from the light-emitting device 550R(i,j) can be converted to red light.

Accordingly, a second light-emitting device can also be formed in the step of forming a first light-emitting device. The hue can be changed with the use of the first light-emitting device and the second light-emitting device. As a result, a novel display panel that is highly convenient, useful, or reliable can be provided.

### Structure Example 10 of Display Panel 700

The structure of the display panel of one embodiment of the present invention is described with reference to FIG. 9.

Note that the display panel 700 described with reference to FIG. 9 is different from the display panel 700 described with reference to FIG. 4 in that the light-emitting device 550B(i,j) includes a unit 103B2(j) and an intermediate layer 106B(j), and the light-emitting device 550G(i,j) includes a unit 103G2(j) and an intermediate layer 106G(j). The light-emitting device 550R(i,j) includes a unit 103R2(j) and an intermediate layer 106R(j). Different portions will be described in detail here, and the above description is referred to for portions that can use similar structures.

### Structure Example 2 of Light-Emitting Device 550B(i,j)

The light-emitting device 550B(i,j) includes the unit 103B2(j) and the intermediate layer 106B(j) (see FIG. 9A).

The unit 103B2(j) includes a region interposed between the electrode 552B(j) and the unit 103B(j).

### Structure Example 1 of Intermediate Layer 106B(j)

The intermediate layer 106B(j) includes a region interposed between the unit 103B2(j) and the unit 103B(j), and contains a material having a hole-transport property and a substance having an acceptor property. The intermediate layer 106B(j) has an electrical resistivity greater than or equal to 1×10² [Ω·cm] and less than or equal to 1×10⁸ [Ω·cm]. The intermediate layer 106B(j) has a function of supplying electrons to the anode side and supplying holes to the cathode side by applying voltages.

The material having a hole-transport property and the substance having an acceptor property can be used for the intermediate layer 106B(j). For example, a structure that can be used for the layer 104B(j) and the layer 104G(j) can be used for the intermediate layer 106B(j).

For example, a structure that exhibits a different emission color from the emission color of the unit 103B(j) can be used for the unit 103B2(j). Specifically, the unit 103B(j) that emits red light and green light and the unit 103B2(j) that emits blue light can be used. Accordingly, a light-emitting device that emits light of a desired color can be provided. For example, a light-emitting device that emits white light can be provided.

Note that blue light can be extracted from white light emitted from the light-emitting device with the use of the coloring layer CFB(j), green light can be extracted from white light emitted from the light-emitting device with the use of the coloring layer CFG(j), and red light can be extracted from white light emitted from the light-emitting device with the use of the coloring layer CFR(j).

For example, an emission color of the unit 103B(j) can be the same as that of the unit 103B2(j). Specifically, the unit 103B(j) that emits blue light and the unit 103B2(j) that emits blue light can be used. Thus, light emission at high luminance can be obtained while the power consumption is inhibited.

In the case where a color conversion layer is used instead of the coloring layer CFB(j), blue light can be converted into green light or red light. For example, nanoparticles, quantum dots, or the like can be used for the color conversion layer.

### Structure Example 3 of Light-Emitting Device 550G(i,j)

The light-emitting device 550G(i,j) includes the unit 103G2(j) and the intermediate layer 106G(j), and the unit 103G2(j) includes a region interposed between the electrode 552G(j) and the unit 103G(j).

The intermediate layer 106G(j) includes a region interposed between the unit 103G2(j) and the unit 103G(j), and the intermediate layer 106G(j) contains the same material having a hole-transport property and the same substance having an acceptor property as the intermediate layer 106B(j). The intermediate layer 106G(j) includes a gap 1065(j) between the intermediate layer 106G(j) and the intermediate layer 106B(j). Note that the intermediate layer 106B(j) and the intermediate layer 106G(j) have conductivity, and the gap 1065(j) has a function of inhibiting electrical continuity between the intermediate layer 106B(j) and the intermediate layer 106G(j).

### Structure Example 3 of Partition 528

The partition 528 overlaps with the gap 1065(j) between the opening portion 528B(i,j) and the opening portion 528G(i,j) (see FIG. 9A and FIG. 9C).

Thus, a phenomenon in which current flows between the electrode 551B(i,j) and the electrode 552G(j) through the layer 104B(j) and the layer 104G(j) or through the intermediate layer 106B and the intermediate layer 106G can be inhibited. In addition, a phenomenon in which current flows between the electrode 551G(i,j) and the electrode 552B(j) through the layer 104B(j) and the layer 104G(j) or through the intermediate layer 106B and the intermediate layer 106G can be inhibited. Furthermore, occurrence of a crosstalk phenomenon between the light-emitting device 550B(i,j) and the light-emitting device 550G(i,j) can be inhibited. As a result, a novel display panel that is highly convenient, useful, or reliable can be provided.

### Structure Example 11 of Display Panel 700

The structure of the display panel of one embodiment of the present invention will be described with reference to FIG. 10 and FIG. 11.

Note that the display panel 700 described with reference to FIG. 10 and FIG. 11 is different from the display panel 700 described with reference to FIG. 9 in that the insulating film 573 is included.

### Structure Example 2 of Layer 104B(j) and Layer 104G(j)

The layer 104B(j) includes a first sidewall WL1, and the layer 104G(j) includes a second sidewall WL2 (see FIG. 11).

The second sidewall WL2 faces the first sidewall WL1, and the gap 104S(j) is interposed between the second sidewall WL2 and the first sidewall WL1.

### Structure Example 3 of Insulating Film 573

The insulating film 573 is in contact with the first sidewall WL1 and the second sidewall WL2.

### Structure Example 4 of Insulating Film 573

The insulating film 573 is in contact with the partition 528 (see FIG. 11).

### Structure Example 5 of Insulating Film 573

The insulating film 573 includes the insulating film 573A and the insulating film 573B.

The insulating film 573A is interposed between the insulating film 573B and the electrode 552B(j), and the insulating film 573A is interposed between the insulating film 573B and the electrode 552G(j).

### Structure Example 12 of Display Panel 700

The structure of the display panel of one embodiment of the present invention will be described with reference to FIG. 12.

Note that the display panel 700 described with reference to FIG. 12 is different from the display panel 700 described with reference to FIG. 9 in that a gap CFS(j) is included between the coloring layer CFG(j) and the coloring layer CFB(j), and the insulating film 573 is included between the coloring layer CFB(j) and the electrode 552B(j). Different portions will be described in detail here, and the above description is referred to for portions that can use similar structures.

### Structure Example 2 of Coloring Layer

In addition, the display panel of one embodiment of the present invention includes the gap CFS(j) between the coloring layer CFG(j) and the coloring layer CFB(j) (see FIG. 12). The coloring layer CFG(j) includes a third sidewall on the coloring layer CFB(j) side.

### Structure Example 4 of Light-Emitting Device 550G(i,j)

The unit 103G2(j) includes a fourth sidewall continuous with the third sidewall, and the unit 103G(j) includes a fifth sidewall continuous with the fourth sidewall.

Thus, light emitted from the light-emitting device 550G(i,j) can be efficiently led into the coloring layer CFG(j). As a result, a novel display panel that is highly convenient, useful, or reliable can be provided.

### Structure Example 6 of Insulating Film 573

The display panel of one embodiment of the present invention includes the insulating film 573 between the coloring layer CFB(j) and the electrode 552B(j) and between the coloring layer CFG(j) and the electrode 552G(j) (see FIG. 12). The insulating film 573 is included between the coloring layer CFR(j) and the electrode 552R(j).

For example, a stacked-layer film in which an organic material and an inorganic material are stacked can be used as the insulating film 573. Thus, the insulating film 573 with high quality and less defects can be formed. In addition, in the step of forming the coloring layer CFB(j), the coloring layer CFG(j), and the coloring layer CFR(j), the insulating film 573 can protect the structure interposed between the insulating film 573 and the electrode 551B(i,j), for example. Furthermore, a phenomenon in which impurities are diffused into the light-emitting device 550B(i,j), the light-emitting device 550G(i,j), and the light-emitting device 550R(i,j) can be inhibited.

### Structure Example 13 of Display Panel 700

The structure of the display panel of one embodiment of the present invention will be described with reference to FIG. 13.

Note that the display panel 700 described with reference to FIG. 13 is different from the display panel 700 described with reference to FIG. 9 in that the insulating film 573 is included between the coloring layer CFB(j) and the electrode 552B(j), and the insulating film 573 fills the gap 104S(j).

### Structural Example 14 of Display Panel 700

The structure of the display panel of one embodiment of the present invention will be described with reference to FIG. 14.

Note that the display panel 700 described with reference to FIG. 14 is different from the display panel 700 described with reference to FIG. 9 in that a partition 528(2) is included over the partition 528, and the electrode 552 functions as one electrode of the light-emitting device 550B(i,j), the light-emitting device 550G(i,j), and the light-emitting device 550R(i,j).

For example, after the formation of the layer 104B(j), the unit 103B(j), the intermediate layer 106B, and the unit 103B2 by a photoetching method, the partition 528(2) can be formed over the partition 528 by a photolithography method. Furthermore, the electrode 552 can be formed to cover the unit 103B(j) and the partition 528.

### Structural Example 15 of Display Panel 700

The structure of the display panel of one embodiment of the present invention will be described with reference to FIG. 15.

Note that the display panel 700 described with reference to FIG. 15 is different from the display panel 700 described with reference to FIG. 9 in that the partition 528(2) is included over the partition 528, a large step is included between the partition 528(2) and the electrode 551B(i,j), and the partition 528(2) is provided with an eaves shape in which the upper portion of the partition 528(2) protrudes more than the bottom portion thereof. Thus, electrical continuity between the layer 104B(j) and the layer 104G(j), and electrical continuity between the intermediate layer 106B(j) and the intermediate layer 106G(j) are inhibited.

### Structural Example 16 of Display Panel 700

The structure of the display panel of one embodiment of the present invention will be described with reference to FIG. 16.

Note that the display panel 700 described with reference to FIG. 16 is different from the display panel 700 described with reference to FIG. 9 in that an unit 1032 functions as one unit of the light-emitting device 550B(i,j), the light-emitting device 550G(i,j), and the light-emitting device 550R(i,j), and the electrode 552 functions as one electrode of the light-emitting device 550B(i,j), the light-emitting device 550G(i,j), and the light-emitting device 550R(i,j).

Note that this embodiment can be combined as appropriate with any of the other embodiments described in this specification.

### Embodiment 2

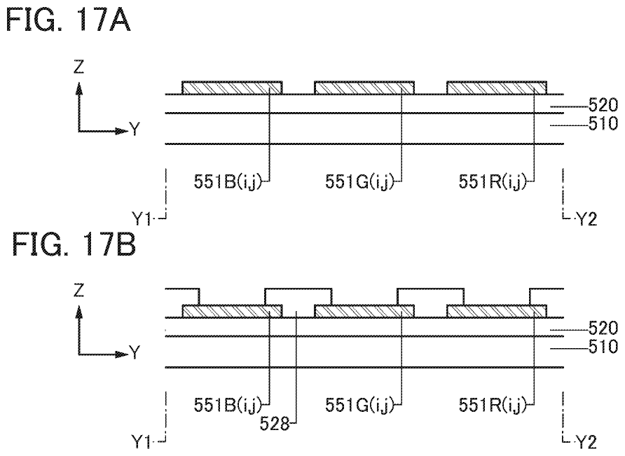

The method for manufacturing the display panel of one embodiment of the present invention will be described with reference to FIG. 17 to FIG. 23.

FIG. 17 to FIG. 20 are diagrams illustrating the method for manufacturing the display panel of one embodiment of the present invention.

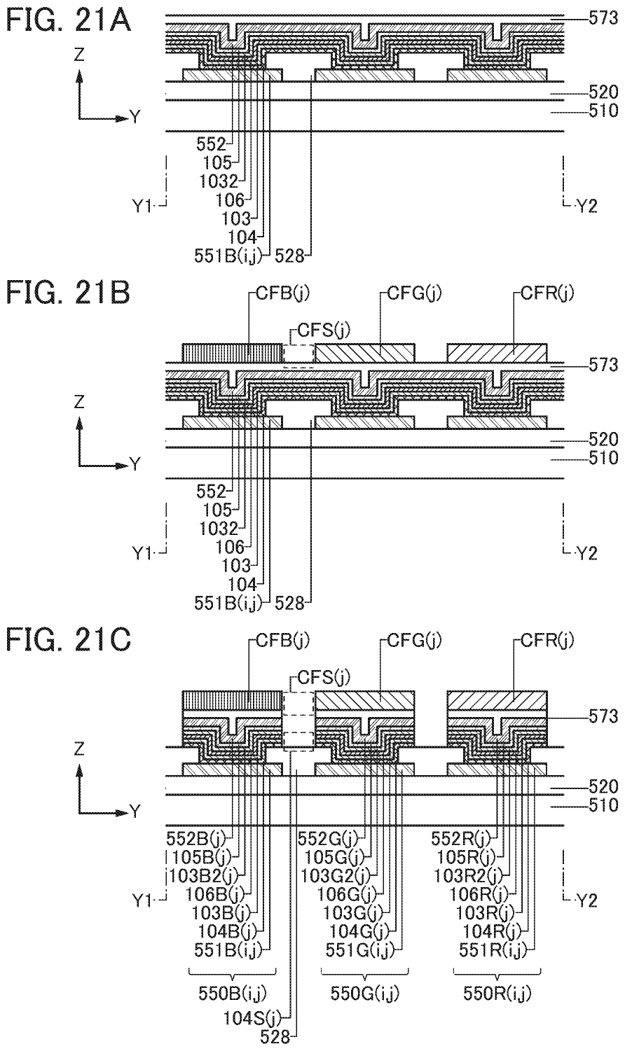

FIG. 21 shows diagrams illustrating a method for manufacturing a display panel of one embodiment of the present invention, which is different from the display panel of one embodiment of the present invention described with reference to FIG. 17 to FIG. 20.

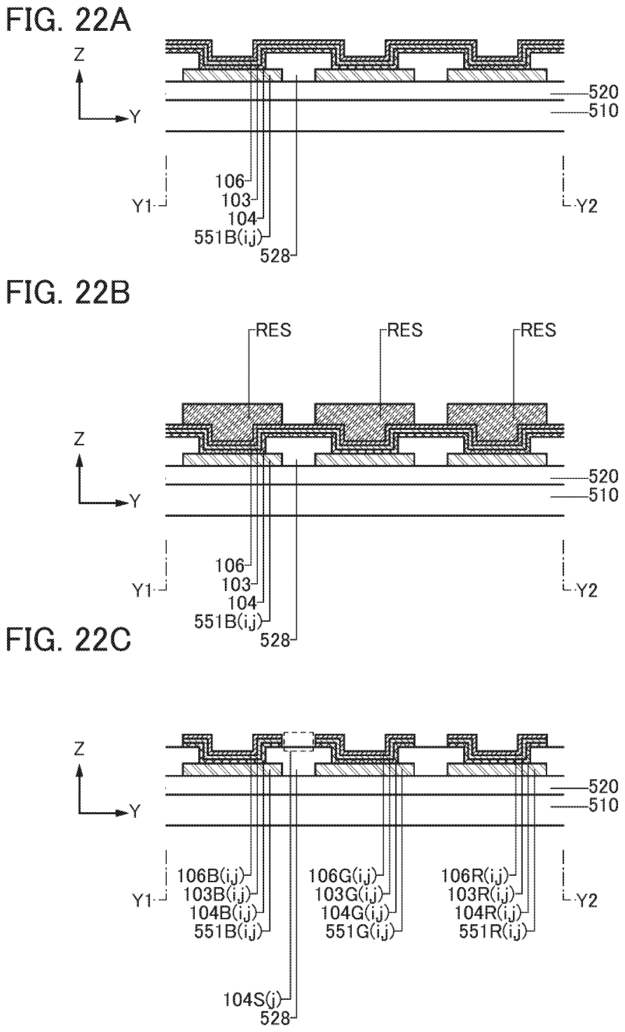

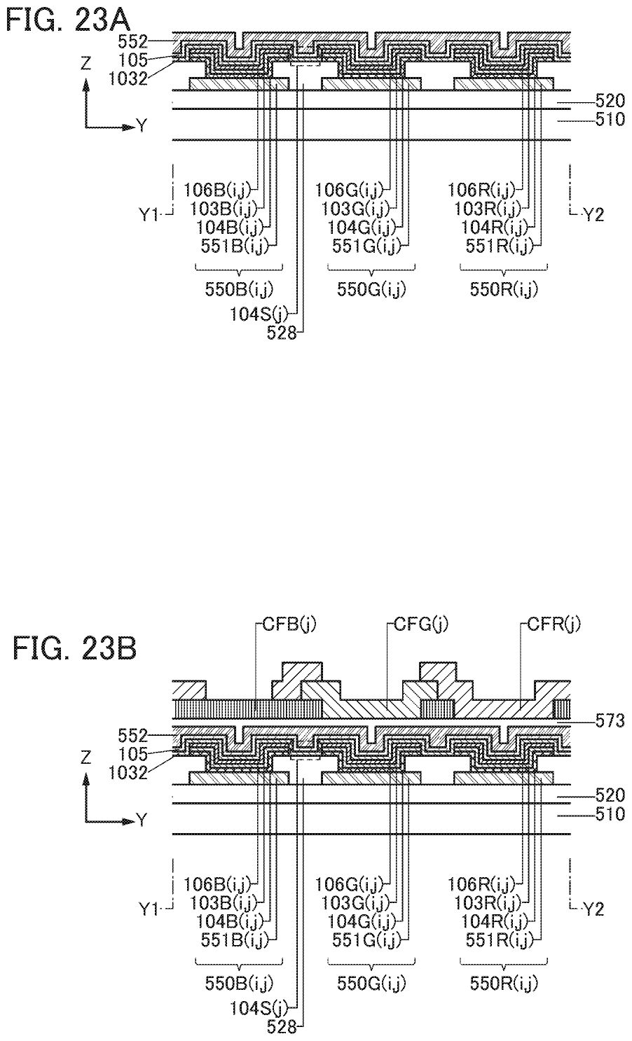

FIG. 22 and FIG. 23 show diagrams illustrating the method for manufacturing the display panel of one embodiment of the present invention, which is different from the display panel of one embodiment of the present invention described with reference to FIG. 17 to FIG. 20.

### Example 1 of Method for Manufacturing Display Panel

The method for manufacturing the display panel of one embodiment of the present invention has a first step to a thirteenth step described below. For example, the display panel 700 of one embodiment of the present invention described with reference to FIG. 5 can be manufactured.

### First Step

In the first step, the electrode 551B(i,j) and the electrode 551G(i,j) are formed. In addition, the electrode 551R(i,j) is formed. For example, a conductive film is formed over the base material 510 and processed into a predetermined shape by a photolithography method (see FIG. 17A).

### Second Step

In the second step, the partition 528 is formed between the electrode 551B(i,j) and the electrode 551G(i,j) and between the electrode 551G(i,j) and the electrode 551R(i,j). For example, an insulating film covering the electrode 551B(i,j) to the electrode 551R(i,j) is formed, and opening portions are formed by a photolithography method to partly expose the electrode 551B(i,j) to the electrode 551R(i,j) (see FIG. 17B).

### Third Step

In the third step, the layer 104B(j) is formed over the electrode 551B(i,j) and the electrode 551G(i,j). For example, the layer 104B(j) is formed by a vacuum evaporation method over the electrode 551B(i,j) and the electrode 551G(i,j) to cover them. Note that the electrode 551R(i,j) is also covered.

### Fourth Step

In the fourth step, the unit 103B(j) is formed over the layer 104B(j). For example, the unit 103B(j) is formed by a vacuum evaporation method.

### Fifth Step

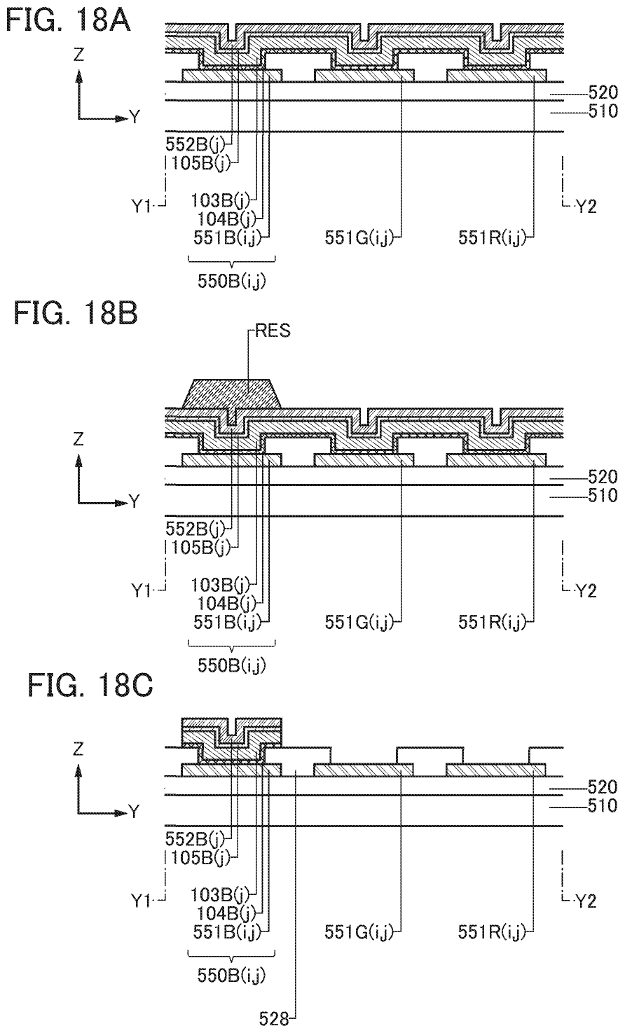

In the fifth step, the layer 105B(j) and the electrode 552B(j) are formed over the unit 103B(j). For example, the layer 105B(j) and the electrode 552B(j) are formed by a vacuum evaporation method (see FIG. 18A).

### Sixth Step

In the sixth step, the layer 104B(j), the unit 103B(j), and the electrode 552B(j) are processed into a predetermined shape (see FIG. 18C). For example, the layer 104B(j), the unit 103B(j), and the electrode 552B(j) over the electrode 551G(i,j) are removed by a photoetching method, and the remaining layer 104B(j), unit 103B(j), and electrode 552B(j) are processed into a belt-like shape extending in the direction intersecting with the sheet. Thus, the light-emitting device 550B(i,j) is formed. Note that the layer 104B(j), the unit 103B(j), and the electrode 552B(j) over the electrode 551R(i,j) are also removed.

Specifically, a resist RES formed over the electrode 552B(j) is used (see FIG. 18B). Moreover, the partition 528 can be used as an etching stopper.

### Seventh Step

In the seventh step, the layer 104G(j) is formed over the electrode 552B(j) and the electrode 551G(i,j). For example, the layer 104G(j) is formed over the electrode 551B(i,j) and the electrode 551G(i,j) by a vacuum evaporation method to cover them. Note that the electrode 551R(i,j) is also covered.

### Eighth Step

In the eighth step, the unit 103G(j) is formed over the layer 104G(j). For example, the unit 103G(j) is formed by a vacuum evaporation method.

### Ninth Step

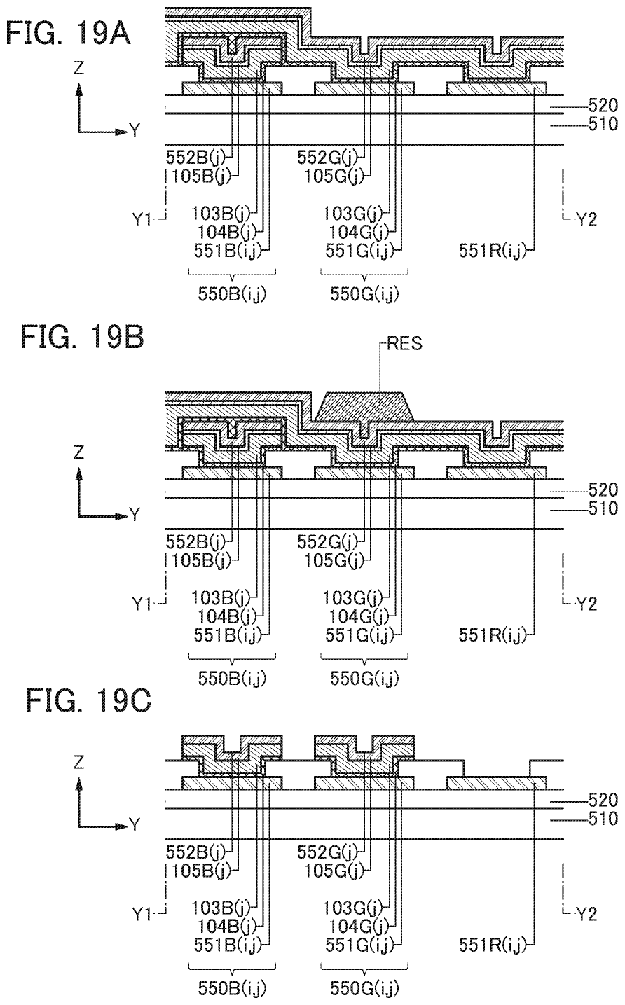

In the ninth step, the electrode 552G(j) is formed over the unit 103G(j). For example, the electrode 552G(j) is formed by a vacuum evaporation method (see FIG. 19A).

### Tenth Step

In the tenth step, the layer 104G(j), the unit 103G(j), and the electrode 552G(j) are processed into a predetermined shape (see FIG. 19C). For example, the layer 104G(j), the unit 103G(j), and the electrode 552G(j) over the electrode 552B(i,j) are removed by a photoetching method, the remaining layer 104G(j), unit 103G(j), and electrode 552G(j) are processed into a belt-like shape extending in the direction intersecting with the sheet, and thus are separated from the light-emitting device 550B(i,j). Thus, the light-emitting device 550G(i,j) is formed. Note that the layer 104G(j), the unit 103G(j), and the electrode 552G(j) over the electrode 551R(i,j) are also removed.

Specifically, the resist RES formed over the electrode 552G(j) is used (see FIG. 19B). Moreover, the partition 528 can be used as an etching stopper.

### Eleventh Step

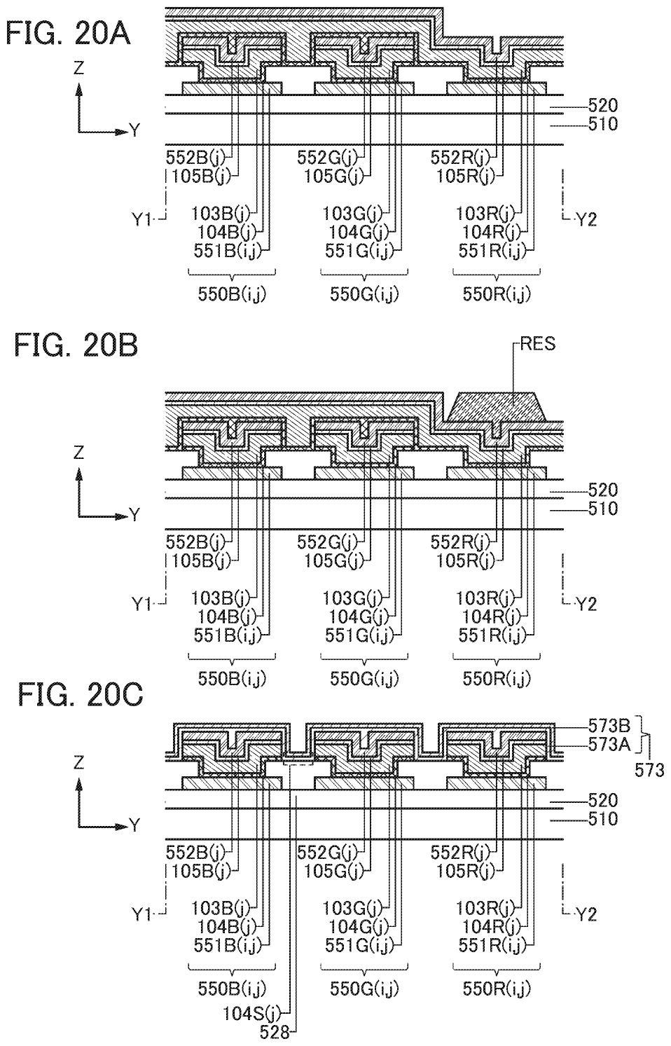

In the eleventh step, the layer 104R(j), the unit 103R(j), the layer 105R(j), and the electrode 552R(j) are formed in this order. For example, the layer 104R(j), the unit 103R(j), the layer 105R(j), and the electrode 552R(j) are formed by a vacuum evaporation method to cover the electrode 551R(i,j) (see FIG. 20A).

### Twelfth Step

In the twelfth step, the layer 104R(j), the unit 103R(j), and the electrode 552R(j) are processed into a predetermined shape (see FIG. 20C). For example, the layer 104R(j), the unit 103R(j), and the electrode 552R(j) are processed into a belt-like shape extending in the direction intersecting with the sheet.

Specifically, the resist RES formed over the layer 104R(j), the unit 103R(j), and the electrode 552R(j) and an etching method are used (see FIG. 20B). The electrode 552B(j), the electrode 552G(j), and the partition 528 can be used as an etching stopper.

Through the above steps, the light-emitting device 550B(i,j), the light-emitting device 550G(i,j), and the light-emitting device 550R(i,j) can be separately formed.

### Thirteenth Step

In the thirteenth step, the insulating film 573 in contact with the partition 528 is formed to cover the light-emitting device 550B(i,j), the light-emitting device 550G(i,j), and the light-emitting device 550R(i,j). Through the above steps, the light-emitting device 550B(i,j), the light-emitting device 550G(i,j), and the light-emitting device 550R(i,j) can be protected with the use of the insulating film 573 (see FIG. 20C).

### Example 2 of Method for Manufacturing Display Panel

The method for manufacturing the display panel of one embodiment of the present invention has a first step to an eighth step described below. For example, the display panel 700 of one embodiment of the present invention described with reference to FIG. 12 can be manufactured.

### First Step

In the first step, the electrode 551B(i,j) and the electrode 551G(i,j) are formed. In addition, the electrode 551R(i,j) is formed. For example, a conductive film is formed over the base material 510 and processed into a predetermined shape by a photolithography method (see FIG. 17A).

### Second Step

In the second step, the partition 528 is formed between the electrode 551B(i,j) and the electrode 551G(i,j). For example, an insulating film covering the electrode 551B(i,j) to the electrode 551R(i,j) is formed, and opening portions are formed by a photolithography method to partly expose the electrode 551B(i,j) to the electrode 551R(i,j) (see FIG. 17B).

### Third Step

In the third step, the layer 104 is formed over the electrode 551B(i,j) and the electrode 551G(i,j). For example, the layer 104 is formed by a vacuum evaporation method over the electrode 551B(i,j) and the electrode 551G(i,j) to cover them. Note that the electrode 551R(i,j) is also covered.

### Fourth Step

In the fourth step, a unit 103 is formed over the layer 104. For example, the unit 103 is formed by a vacuum evaporation method.

### Fifth Step

In the fifth step, a layer 106 is formed over the unit 103. For example, the layer 106 is formed by a vacuum evaporation method.

### Sixth Step

In the sixth step, the unit 1032 is formed over the layer 106. For example, the unit 1032 is formed a vacuum evaporation method.

### Seventh Step

In the seventh step, the electrode 552 is formed over the unit 1032. For example, the electrode 552 is formed by a vacuum evaporation method (see FIG. 21A).

The insulating film 573 is formed over the electrode 552, and the coloring layer CFB(j), the coloring layer CFG(j), and the coloring layer CFR(j) are formed over the insulating film 573 (see FIG. 21B).

For example, the insulating film 573 is formed by stacking a flat film and a dense film. Specifically, the flat film is formed by a coating method, and the dense film is stacked over the flat film by a chemical vapor deposition method, an atomic layer deposition (ALD) method, or the like. Thus, the insulating film 573 with high quality and less defects can be formed.

For example, with the use of a color resist, the coloring layer CFB(j), the coloring layer CFG(j), and the coloring layer CFR(j) are formed into a predetermined shape. Note that the coloring layer CFG(j) is formed in a position apart from the coloring layer CFB(j), and the gap CFS(j) is formed between the coloring layer CFG(j) and the coloring layer CFB(j).

### Eighth Step

In the eighth step, the layer 104, the unit 103, the layer 106, the unit 1032, the electrode 552, and the insulating film 573 are processed into a predetermined shape (see FIG. 21C). For example, the layer 104, the unit 103, the layer 106, the unit 1032, the electrode 552, and the insulating film 573 are processed into a belt-like shape extending in the direction intersecting with the sheet.

Specifically, by using a resist formed over the coloring layer CFB(j), the coloring layer CFG(j), and the coloring layer CFR(j) and an etching method, a portion overlapping with the gap CFS(j) is removed. Alternatively, the coloring layer CFB(j), the coloring layer CFG(j), and the coloring layer CFR(j) may be used for the resist. Moreover, the partition 528 can be used as an etching stopper.

The layer 104 is processed into the layer 104B(j), the layer 104G(j), and the layer 104R(j). The unit 103 is processed into the unit 103B(j), the unit 103G(j), and the unit 103R(j). The layer 106 is processed into the intermediate layer 106B(j), the intermediate layer 106G(j), and the intermediate layer 106R(j). The unit 1032 is processed into the unit 103B2(j), the unit 103G2(j), and the unit 103R2(j). The electrode 552 is processed into the electrode 552B(j), the electrode 552G(j), and the electrode 552R(j). For example, the gap 1045(j) inhibits electrical continuity between the layer 104B(j) and the layer 104G(j), and electrical continuity between the intermediate layer 106B(j) and the intermediate layer 106G(j).

Through the above steps, the light-emitting device 550B(i,j), the light-emitting device 550G(i,j), and the light-emitting device 550R(i,j) can be separately formed.

### Example 3 of Method for Manufacturing Display Panel

The method for manufacturing the display panel of one embodiment of the present invention has a first step to a sixth step described below. For example, the display panel 700 of one embodiment of the present invention described with reference to FIG. 16 can be manufactured.

### First Step

In the first step, the electrode 551B(i,j) and the electrode 551G(i,j) are formed. In addition, the electrode 551R(i,j) is formed. For example, a conductive film is formed over the base material 510 and processed into a predetermined shape by a photolithography method (see FIG. 17A).

### Second Step

In the second step, the partition 528 is formed between the electrode 551B(i,j) and the electrode 551G(i,j) and between the electrode 551G(i,j) and the electrode 551R(i,j). For example, an insulating film covering the electrode 551B(i,j) to the electrode 551R(i,j) is formed, and opening portions are formed by a photolithography method to partly expose the electrode 551B(i,j) to the electrode 551R(i,j) (see FIG. 17B).

### Third Step

In the third step, the layer 104, the unit 103, and the layer 106 are formed in this order over the electrode 551B(i,j) and the electrode 551G(i,j) (see FIG. 22A). For example, the layer 104, the unit 103, and the layer 106 are formed by a vacuum evaporation method over the electrode 551B(i,j) and the electrode 551G(i,j) to cover them. Note that the electrode 551R(i,j) is also covered.

### Fourth Step

In the fourth step, the layer 104, the unit 103, and the layer 106 are processed into a predetermined shape (see FIG. 22C). For example, the layer 104, the unit 103, and the layer 106 are processed into an island shape overlapping with the electrode 551B(i,j) and an island shape overlapping with the electrode 551G(i,j). Alternatively, the layer 104, the unit 103, and the layer 106 may be processed into a belt-like shape extending in the direction intersecting with the sheet. In addition, the layer 104, the unit 103, and the layer 106 are processed into the shape overlapping with the electrode 551R(i,j).

Specifically, the resist RES formed over the layer 104, the unit 103, and the layer 106, and an etching method are used (see FIG. 22B). Moreover, the partition 528 can be used as an etching stopper.

The layer 104 is processed into the layer 104B(i,j), the layer 104G(i,j), and the layer 104R(i,j). The unit 103 is processed into the unit 103B(i,j), the unit 103G(i,j), and the unit 103R(i,j). The layer 106 is processed into an intermediate layer 106B(i,j), an intermediate layer 106G(i,j), and an intermediate layer 106R(i,j). For example, the gap 104S(j) inhibits electrical continuity between the layer 104B(i,j) and the layer 104G(i,j), and electrical continuity between the intermediate layer 106B(i,j) and the intermediate layer 106G(i,j).

### Fifth Step

In the fifth step, the unit 1032, the layer 105, and the electrode 552 are formed in this order (see FIG. 23A). For example, the unit 1032, the layer 105, and the electrode 552 are formed by a vacuum evaporation method to cover the intermediate layer 106B(i,j), the intermediate layer 106G(i,j), and the intermediate layer 106R(i,j).

### Sixth Step

In the sixth step, the insulating film 573, the coloring layer CFB(j), the coloring layer CFG(j), and the coloring layer CFR(j) are formed (see FIG. 23B).

For example, the insulating film 573 is formed by stacking a flat film and a dense film. Specifically, the flat film is formed by a coating method, and the dense film is stacked over the flat film by a chemical vapor deposition method, an atomic layer deposition (ALD) method, or the like. Thus, the insulating film 573 with high quality and less defects can be formed.

For example, with the use of a color resist, the coloring layer CFB(j), the coloring layer CFG(j), and the coloring layer CFR(j) are formed into a predetermined shape. Note that the coloring layers are processed so that the coloring layer CFR(j) and the coloring layer CFB(j) overlap with each other over the partition 528. Thus, a phenomenon of entrance of light emitted from an adjacent light-emitting device can be inhibited.

Note that this embodiment can be combined as appropriate with any of the other embodiments described in this specification.

### Embodiment 3

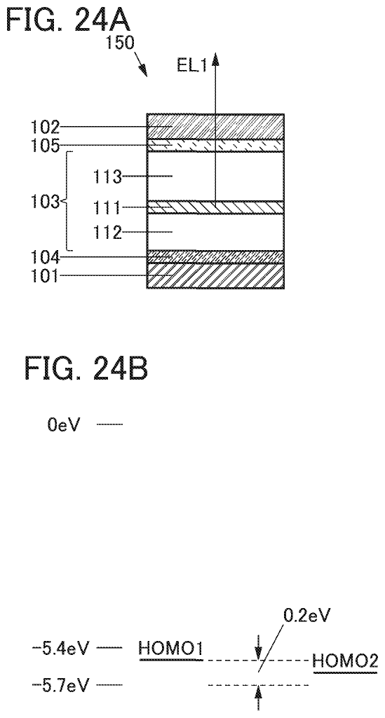

In this embodiment, a structure of a light-emitting device 150 that can be used for the display panel of one embodiment of the present invention will be described with reference to FIG. 24A. Note that the structure that can be used for the light-emitting device 150 can be used for the light-emitting device 550B(i,j), the light-emitting device 550G(i,j), or the light-emitting device 550R(i,j), for example, described in Embodiment 1.

### Structure Example of Light-Emitting Device 150

The light-emitting device 150 described in this embodiment includes an electrode 101, an electrode 102, and the unit 103. The electrode 102 includes a region overlapping with the electrode 101, and the unit 103 includes a region interposed between the electrode 101 and the electrode 102. Note that the structure that can be used for the unit 103 can be used for, for example, the unit 103B(j), the unit 103G(j), or the unit 103R(j) described in Embodiment 1.

### Structure Example of Unit 103

The unit 103 has a single-layer structure or a stacked-layer structure. For example, the unit 103 includes a layer 111, a layer 112, and the layer 113 (see FIG. 24A). The unit 103 has a function of emitting light EL 1.

The layer 111 includes a region interposed between the layer 112 and the layer 113, the layer 112 includes a region interposed between the electrode 101 and the layer 111, and the layer 113 includes a region interposed between the electrode 102 and the layer 111.

The unit 103 can include, for example, a layer selected from a light-emitting layer, a hole-transport layer, an electron-transport layer, a carrier-blocking layer, and the like. The unit 103 can include a layer selected from a hole-injection layer, an electron-injection layer, an exciton-blocking layer, a charge-generation layer, and the like.

### Structure Example of Layer 112

A material having a hole-transport property can be used for the layer 112, for example. The layer 112 can be referred to as a hole-transport layer. A material having a wider bandgap than the light-emitting material contained in the layer 111 is preferably used for the layer 112. Thus, transfer of energy from excitons generated in the layer 111 to the layer 112 can be inhibited.

### Hole-Transport Material

A material having a hole mobility of 1×10⁻⁶ cm²/Vs or higher can be suitably used as the material having a hole-transport property.

As the material having a hole-transport property, an amine compound or an organic compound having a π-electron rich heteroaromatic ring skeleton can be used, for example. Specifically, a compound having an aromatic amine skeleton, a compound having a carbazole skeleton, a compound having a thiophene skeleton, a compound having a furan skeleton, or the like can be used. The compound having an aromatic amine skeleton and the compound having a carbazole skeleton are particularly preferable because these compounds are highly reliable and have high hole-transport properties to contribute to a reduction in driving voltage.

### Structure Example of Layer 113

A material having an electron-transport property, a material having an anthracene skeleton, and a mixed material can be used for the layer 113, for example. The layer 113 can be referred to as an electron-transport layer. A material having a wider bandgap than the light-emitting material contained in the layer 111 is preferably used for the layer 113. Thus, energy transfer from excitons generated in the layer 111 to the layer 113 can be inhibited.

### Electron-Transport Material

For example, a metal complex or an organic compound having a π-electron deficient heteroaromatic ring skeleton can be used as the material having an electron-transport property.

As the material having an electron-transport property, a material having an electron mobility higher than or equal to 1×10⁻⁷ cm²/Vs and lower than or equal to 5×10⁻⁵ cm²/Vs when the square root of the electric field strength [V/cm] is 600 can be suitably used. In this case, the electron-transport property in the electron-transport layer can be inhibited. Alternatively, the amount of electrons injected into the light-emitting layer can be controlled. Alternatively, the light-emitting layer can be prevented from having excess electrons.

As the organic compound having a π-electron deficient heteroaromatic ring skeleton, for example, a heterocyclic compound having a polyazole skeleton, a heterocyclic compound having a diazine skeleton, a heterocyclic compound having a pyridine skeleton, a heterocyclic compound having a triazine skeleton, or the like can be used. In particular, the heterocyclic compound having a diazine skeleton and the heterocyclic compound having a pyridine skeleton have favorable reliability and thus are preferable. In addition, the heterocyclic compound having a diazine (pyrimidine or pyrazine) skeleton has a high electron-transport property to contribute to a reduction in driving voltage.

### Material Having Anthracene Skeleton

An organic compound having an anthracene skeleton can be used for the layer 113. In particular, an organic compound having both an anthracene skeleton and a heterocyclic skeleton can suitably be used.

For example, it is possible to use an organic compound having both an anthracene skeleton and a nitrogen-containing five-membered ring skeleton. Alternatively, it is possible to use an organic compound having both an anthracene skeleton and a nitrogen-containing five-membered ring skeleton where two heteroatoms are included in a ring. Specifically, it is suitable to use, as the heterocyclic skeleton, a pyrazole ring, an imidazole ring, an oxazole ring, a thiazole ring, or the like.

For example, it is possible to use an organic compound having both an anthracene skeleton and a nitrogen-containing six-membered ring skeleton. Alternatively, it is possible to use an organic compound having both an anthracene skeleton and a nitrogen-containing six-membered ring skeleton where two heteroatoms are included in a ring. Specifically, it is suitable to use, as the heterocyclic skeleton, a pyrazine ring, a pyrimidine ring, a pyridazine ring, or the like.

### Structure Example of Mixed Material

A material in which a plurality of kinds of substances are mixed can be used for the layer 113. Specifically, a mixed material which includes an alkali metal, an alkali metal compound, or an alkali metal complex and a substance having an electron-transport property can be used for the layer 113. Note that the material having an electron-transport property preferably has a HOMO level of −6.0 eV or higher.

For example, a composite material of a substance having an acceptor property and a material having a hole-transport property can be used for the layer 104. Specifically, a composite material of the substance having an acceptor property and a substance having a relatively deep HOMO level HOMO1, which is greater than or equal to −5.7 eV and less than or equal to −5.4 eV, can be used for the layer 104 (see FIG. 24B). The mixed material can be suitably used for the layer 113 in combination with a structure using such a composite material for the layer 104. This leads to an increase in the reliability of the light-emitting device.

Furthermore, a structure using a material having a hole-transport property for the layer 112 can be suitably combined with the structure using the mixed material for the layer 113 and the composite material for the layer 104. For example, a substance having a HOMO level HOMO2, which is within the range of ˜0.2 eV to 0 eV, inclusive, from the relatively deep HOMO level HOMO1, can be used for the layer 112 (see FIG. 24B). This leads to an increase in the reliability of the light-emitting device.

The concentration of the alkali metal, the alkali metal compound, or the alkali metal complex preferably differs in the thickness direction of the layer 113 (including the case where the concentration is 0).

For example, a metal complex having an 8-hydroxyquinolinato structure can be used. A methyl-substituted product of the metal complex having an 8-hydroxyquinolinato structure (e.g., a 2-methyl-substituted product or a 5-methyl-substituted product) or the like can also be used.

### Structure Example 1 of Layer 111

A light-emitting material or a light-emitting material and a host material can be used for the layer 111, for example. The layer 111 can be referred to as a light-emitting layer. Note that the layer 111 is preferably provided in a region where holes and electrons are recombined. Thus, energy generated by recombination of carriers can be efficiently converted into light and emitted. Furthermore, the layer 111 is preferably provided to be distanced from a metal used for the electrode or the like. Thus, a quenching phenomenon caused by the metal used for the electrode or the like can be inhibited.

For example, a fluorescent substance, a phosphorescent substance, or a substance exhibiting thermally activated delayed fluorescence TADF (also referred to as a TADF material) can be used for the light-emitting material. Thus, energy generated by recombination of carriers can be released as light EL1 from the light-emitting material (see FIG. 24A).

### Fluorescent Substance

A fluorescent substance can be used for the layer 111. For example, any of the following fluorescent substances can be used for the layer 111. Note that the fluorescent substance that can be used for the layer 111 is not limited to the following, and a variety of known fluorescent substances can be used.

Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

### Phosphorescent Substance

A phosphorescent substance can be used for the layer 111. For example, the following phosphorescent substances can be used for the layer 111. Note that the phosphorescent substance that can be used for the layer 111 is not limited to the following, and a variety of known phosphorescent substances can be used.

Any of the following can be used for the layer 111: an organometallic iridium complex having a 4H-triazole skeleton, an organometallic iridium complex having a 1H-triazole skeleton, an organometallic iridium complex having an imidazole skeleton, an organometallic iridium complex having a phenylpyridine derivative with an electron-withdrawing group as a ligand, an organometallic iridium complex having a pyrimidine skeleton, an organometallic iridium complex having a pyrazine skeleton, an organometallic iridium complex having a pyridine skeleton, a rare earth metal complex, a platinum complex, and the like.

### Substance Exhibiting Thermally Activated Delayed Fluorescence (TADF)

A TADF material can be used for the layer 111. For example, any of the TADF materials given below can be used as the light-emitting material. Note that without being limited thereto, a variety of known TADF materials can be used as the light-emitting material.

In the TADF material, the difference between the S1 level and the T1 level is small, and reverse intersystem crossing (upconversion) from the triplet excited state into the singlet excited state can be performed with a small amount of thermal energy. Thus, the singlet excited state can be efficiently generated from the triplet excited state. In addition, the triplet excitation energy can be converted into luminescence.

An exciplex whose excited state is formed of two kinds of substances has an extremely small difference between the S1 level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

When a TADF material is used as the light-emitting substance, the S1 level of the host material is preferably higher than that of the TADF material. In addition, the T1 level of the host material is preferably higher than that of the TADF material.

Examples of the TADF material include a fullerene, a derivative thereof, an acridine, a derivative thereof, and an eosin derivative. Furthermore, porphyrin containing a metal such as magnesium (Mg), zinc (Zn), cadmium (Cd), tin (Sn), platinum (Pt), indium (In), or palladium (Pd) can be also used for the TADF material.

Furthermore, a heterocyclic compound including one or both of a π-electron rich heteroaromatic ring and a π-electron deficient heteroaromatic ring can be used, for example, for the TADF material.

Such a heterocyclic compound is preferable because of having excellent electron-transport property and hole-transport property owing to a π-electron rich heteroaromatic ring and a π-electron deficient heteroaromatic ring. Among skeletons having the π-electron deficient heteroaromatic ring, in particular, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and favorable reliability.

Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which the π-electron rich heteroaromatic ring is directly bonded to the π-electron deficient heteroaromatic ring is particularly preferable because the electron-donating property of the π-electron rich heteroaromatic ring and the electron-acceptor property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used.

As described above, a π-electron deficient skeleton and a π-electron rich skeleton can be used instead of at least one of the π-electron deficient heteroaromatic ring and the π-electron rich heteroaromatic ring.

### Structure Example 2 of Layer 111

A material having a carrier-transport property can be used as the host material. For example, a material having a hole-transport property, a material having an electron-transport property, a substance exhibiting thermally activated delayed fluorescence TADF, a material having an anthracene skeleton, or a mixed material can be used as the host material. A material having a wider bandgap than the light-emitting material contained in the layer 111 is preferably used as the host material. Thus, transfer of energy from excitons generated in the layer 111 to the host material can be inhibited.

### Hole-Transport Material

A material having a hole mobility of 1×10⁻⁶ cm²/Vs or higher can be suitably used as the material having a hole-transport property.

For example, a material having a hole-transport property that can be used for the layer 112 can be used for the layer 111. Specifically, a material having a hole-transport property that can be used for the hole-transport layer can be used for the layer 111.

### Electron-Transport Material

For example, a material having an electron-transport property that can be used for the layer 113 can be used for the layer 111. Specifically, a material having an electron-transport property that can be used for the electron-transport layer can be used for the layer 111.

### Material Having Anthracene Skeleton

An organic compound having an anthracene skeleton can be used as the host material. In particular, when a fluorescent substance is used as the light-emitting substance, an organic compound having an anthracene skeleton is suitable. Thus, a light-emitting device with high emission efficiency and high durability can be achieved.

Among the organic compounds having an anthracene skeleton, an organic compound having a diphenylanthracene skeleton, in particular, a 9,10-diphenylanthracene skeleton is chemically stable and thus is preferable. The host material preferably has a carbazole skeleton in order to improve the hole-injection and hole-transport properties. In particular, the host material preferably has a dibenzocarbazole skeleton because the HOMO level thereof is shallower than that of carbazole by approximately 0.1 eV, so that holes enter the host material easily, the hole-transport property is improved, and the heat resistance is increased. Note that in terms of the hole-injection and hole-transport properties, instead of a carbazole skeleton, a benzofluorene skeleton or a dibenzofluorene skeleton may be used.

Thus, a substance having both a 9,10-diphenylanthracene skeleton and a carbazole skeleton, a substance having both a 9,10-diphenylanthracene skeleton and a benzocarbazole skeleton, or a substance having both a 9,10-diphenylanthracene skeleton and a dibenzocarbazole skeleton is preferably used as the host material.

### Substance Exhibiting Thermally Activated Delayed Fluorescence (TADF)

A TADF material can be used as the host material. When the TADF material is used as the host material, triplet excitation energy generated in the TADF material can be converted into singlet excitation energy by reverse intersystem crossing. Moreover, excitation energy can be transferred to the light-emitting substance. In other words, the TADF material functions as an energy donor, and the light-emitting substance functions as an energy acceptor. Thus, the emission efficiency of the light-emitting device can be increased.

This is very effective in the case where the light-emitting substance is a fluorescent substance. In that case, the S1 level of the TADF material is preferably higher than that of the fluorescent substance in order that high emission efficiency be achieved. Furthermore, the T1 level of the TADF material is preferably higher than the S1 level of the fluorescent substance. Therefore, the T1 level of the TADF material is preferably higher than that of the fluorescent substance.

It is also preferable to use a TADF material that emits light whose wavelength overlaps with the wavelength on a lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no n bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no n bond are poor in carrier-transport performance, whereby the TADF material and the luminophore of the fluorescent substance can be made away from each other with little influence on carrier transportation or carrier recombination.

Here, the luminophore refers to an atomic group (skeleton) that causes light emission in a fluorescent substance. The luminophore is preferably a skeleton having a n bond, further preferably includes an aromatic ring, still further preferably includes a condensed aromatic ring or a condensed heteroaromatic ring.

Examples of the condensed aromatic ring or the condensed heteroaromatic ring include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

For example, the TADF material that can be used as the light-emitting material can be used as the host material.

### Structure Example 1 of Mixed Material

A material in which a plurality of kinds of substances are mixed can be used as the host material. For example, a material having an electron-transport property and a material having a hole-transport property can be used for the mixed material. The weight ratio between the material having a hole-transport property and the material having an electron-transport property contained in the mixed material may be (the material having a hole-transport property/the material having an electron-transport property)=(1/19) or more and (19/1) or less. Accordingly, the carrier-transport property of the layer 111 can be easily adjusted. A recombination region can also be controlled easily.

### Structure Example 2 of Mixed Material

A material mixed with a phosphorescent substance can be used as the host material. When a fluorescent substance is used as the light-emitting substance, a phosphorescent substance can be used as an energy donor for supplying excitation energy to the fluorescent substance.

A mixed material containing a material to form an exciplex can be used as the host material. For example, a material in which an emission spectrum of an exciplex to be formed overlaps with a wavelength of the absorption band on the lowest energy side of the light-emitting substance can be used as the host material. This enables smooth energy transfer and improves emission efficiency. The driving voltage can be inhibited.

A phosphorescent substance can be used as at least one of the materials forming an exciplex. Accordingly, reverse intersystem crossing can be utilized. Triplet excitation energy can be efficiently converted into singlet excitation energy.

A combination of a material having an electron-transport property and a material having a hole-transport property whose HOMO level is higher than or equal to that of the material having an electron-transport property is preferable for forming an exciplex. The LUMO level of the material having a hole-transport property is preferably higher than or equal to the LUMO level of the material having an electron-transport property. Thus, an exciplex can be efficiently formed. Note that the LUMO levels and the HOMO levels of the materials can be derived from the electrochemical characteristics (the reduction potentials and the oxidation potentials). Specifically, the reduction potentials and the oxidation potentials can be measured by cyclic voltammetry (CV).

The formation of an exciplex can be confirmed by a phenomenon in which the emission spectrum of the mixed film in which the material having a hole-transport property and the material having an electron-transport property are mixed is shifted to a longer wavelength side than the emission spectrum of each of the materials (or has another peak on the longer wavelength side) observed in comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed in comparison of transient PL of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed in comparison of the transient EL of the material having a hole-transport property, the transient EL of the material having an electron-transport property, and the transient EL of the mixed film of these materials.

Note that this embodiment can be combined with any of the other embodiments described in this specification as appropriate.

### Embodiment 4

In this embodiment, a structure of the light-emitting device 150 that can be used for the display panel of one embodiment of the present invention will be described with reference to FIG. 24A. Note that the structure of the light-emitting device 150 can be used for the light-emitting device 550B(i,j), the light-emitting device 550G(i,j), or the light-emitting device 550R(i,j) described in Embodiment 1, for example.

### Structural Example of Light-Emitting Device 150

The light-emitting device 150 described in this embodiment includes the electrode 101, the electrode 102, the unit 103, and the layer 104. The electrode 102 includes a region overlapping with the electrode 101, and the unit 103 includes a region interposed between the electrode 101 and the electrode 102. The layer 104 includes a region interposed between the electrode 101 and the unit 103. Note that the structure that can be used for the electrode 101 can be used for the electrode 551B(i,j), the electrode 551G(i,j), or the electrode 551R(i,j) described in Embodiment 1. The structure that can be used for the layer 104 can be used for the layer 104B(j), the layer 104G(j), or the layer 104R(j) described in Embodiment 1.

### Structure Example of Electrode 101

For example, a conductive material can be used for the electrode 101. Specifically, a metal, an alloy, a conductive compound, a mixture of these, or the like can be used for the electrode 101. For example, a material having a work function higher than or equal to 4.0 eV can be suitably used.

For example, indium oxide-tin oxide (ITO: Indium Tin Oxide), indium oxide-tin oxide containing silicon or silicon oxide, indium oxide-zinc oxide, indium oxide containing tungsten oxide and zinc oxide (IWZO), or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), a nitride of a metal material (e.g., titanium nitride), or the like can be used. Alternatively, graphene can be used.

### Structure Example 1 of Layer 104

For example, a material having a hole-injection property can be used for the layer 104. The layer 104 can be referred to as a hole-injection layer.

For example, a material having a hole mobility lower than or equal to 1×10⁻³ cm/Vs when the square root of the electric field strength [V/cm] is 600 can be used for the layer 104. A film having a resistivity greater than or equal to 1×10⁴ [Ω·cm] and less than or equal to 1×10⁷ [Ω·cm] can be used as the layer 104. The resistivity of the layer 104 is preferably greater than or equal to 5×10⁴ [Ω·cm] and less than or equal to 1×10⁷ [Ω·cm], further preferably greater than or equal to 1×10⁵ [Ω·cm] and less than or equal to 1×10⁷ [Ω·cm].

### Structure Example 2 of Layer 104

Specifically, a substance having an acceptor property can be used for the layer 104. A composite material containing a plurality of kinds of substances can be used for the layer 104. This can facilitate injection of holes from the electrode 101, for example. Alternatively, the driving voltage of the light-emitting device 150 can be lowered.

### Substance Having Acceptor Property

An organic compound and an inorganic compound can be used as the substance having an acceptor property. The substance having an acceptor property can extract electrons from an adjacent hole-transport layer or an adjacent material having a hole-transport property by the application of an electric field.

For example, a compound having an electron-withdrawing group (a halogen group or a cyano group) can be used as the substance having an acceptor property. Note that an organic compound having an acceptor property is easily evaporated and deposited. As a result, the productivity of the light-emitting device 150 can be increased.

Specifically, it is possible to use, for example, 7,7,8,8-tetracyano-2,3,5,6-tetrafluoroquinodim ethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene)malononitrile.

A compound in which electron-withdrawing groups are bonded to a condensed aromatic ring having a plurality of heteroatoms, such as HAT-CN, is particularly preferable because it is thermally stable.

Alternatively, a [3]radialene derivative having an electron-withdrawing group (in particular, a cyano group or a halogen group such as a fluoro group) is preferable because it has a very high electron-accepting property.

Specifically, it is possible to use, for example, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], or α,α′,α″-1,2,3-cyclopropanetriylidenetris[2,3,4,5,6-pentafluorobenzeneacetonitrile].

As the substance having an acceptor property, molybdenum oxide, vanadium oxide, ruthenium oxide, tungsten oxide, manganese oxide, or the like can be used.

Alternatively, it is possible to use phthalocyanine (abbreviation: H₂Pc), a phthalocyanine-based complex compound such as and copper phthalocyanine (CuPc), and compounds having an aromatic amine skeleton such as 4,4′-bis[N-(4-diphenylaminophenyl)-N-phenylamino]biphenyl (abbreviation: DPAB) and N,N′-bis{4-[bis(3-methylphenyl)amino]phenyl}-N,N′-diphenyl-(1,1′-biphenyl)-4,4′-diamine (abbreviation: DNTPD).

Alternatively, a high molecular compound such as poly(3,4-ethylenedioxythiophene)/poly(styrenesulfonic acid) (PEDOT/PSS), or the like can be used.

### Structure Example 1 of Composite Material

For example, a composite material containing a substance having an acceptor property and a material having a hole-transport property can be used for the layer 104. Thus, besides a material having a high work function, a material having a low work function can also be used for the electrode 101. Alternatively, a material used for the electrode 101 can be selected from a wide range of materials regardless of its work function.

As the material having a hole-transport property in the composite material, for example, a compound having an aromatic amine skeleton, a carbazole derivative, an aromatic hydrocarbon, an aromatic hydrocarbon having a vinyl group, a high molecular compound (such as an oligomer, a dendrimer, or a polymer), or the like can be used. A material having a hole mobility of 1×10⁻⁶ cm²/Vs or higher can be suitably used as the material having a hole-transport property in the composite material.

A substance having a relatively deep HOMO level can be suitably used as the material having a hole-transport property in the composite material. Specifically, the HOMO level is preferably higher than or equal to −5.7 eV and lower than or equal to −5.4 eV. Accordingly, hole injection to the unit 103 can be facilitated. Alternatively, hole injection to the layer 112 can be facilitated. Alternatively, the reliability of the light-emitting device 150 can be increased.

As the compound having an aromatic amine skeleton, for example, N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis{4-[bis(3-methylphenyl)amino]phenyl}-N,N′-diphenyl-(1,1′-biphenyl)-4,4′-diamine (abbreviation: DNTPD), 1,3,5-tris[N-(4-diphenylaminophenyl)-N-phenylamino]benzene (abbreviation: DPA3B), or the like can be used.

As the carbazole derivative, for example, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), 1,4-bis[4-(N-carbazolyl)phenyl]-2,3,5,6-tetraphenylbenzene, or the like can be used.

As the aromatic hydrocarbon, for example, 2-tert-butyl-9,10-di(2-naphthyl)anthracene (abbreviation: t-BuDNA), 2-tert-butyl-9,10-di(1-naphthyl)anthrac ene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, coronene, or the like can be used.

As the aromatic hydrocarbon having a vinyl group, for example, 4,4′-bis(2,2-diphenylvinyl)biphenyl (abbreviation: DPVBi), 9,10-bis[4-(2,2-diphenylvinyl)phenyl]anthracene (abbreviation: DPVPA), or the like can be used.

As the high molecular compound, for example, poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N-phenylamino}phenyl)methacrylamide] (abbreviation: PTPDMA), poly[N,N′-bis(4-butylphenyl)-N,N′-bis(phenyl)benzidine] (abbreviation: Poly-TPD), or the like can be used.

Furthermore, a substance having any of a carbazole skeleton, a dibenzofuran skeleton, a dibenzothiophene skeleton, and an anthracene skeleton can be suitably used as the material having a hole-transport property in the composite material, for example. Moreover, as the material having a hole-transport property in the composite material, it is possible to use an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group. With the use of a substance including an N,N-bis(4-biphenyl)amino group, the reliability of the light-emitting device 150 can be increased.

As these materials, for example, N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBA(31\TB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-diphenyl-4′-(2-naphthyl)-4″-{9-(4-biphenylyl)carbazole)}triphenylamine (abbreviation: YGTBiβNB), N-[4-(9-phenyl-9Hcarbazol-3-yl)phenyl]-N-[4-(1-naphthyl)phenyl]-9,9′-spirobi(9H-fluoren)-2-amine (abbreviation: PCBNBSF), N,N-bis(4-biphenylyl)-9,9′-spirobi[9H-fluoren]-2-amine (abbreviation: BBASF), N,N-bis(1,1′-biphenyl-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi(9H-fluoren)-4-amine (abbreviation: oFBiSF), N-(4-biphenyl)-N-(dibenzofuran-4-yl)-9,9-dimethyl-9H-fluoren-2-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]spiro-9,9′-bifluoren-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, N,N-bis(9,9-dimethyl-9H-fluoren-2-yl)-9,9′-spirobi-9H-fluoren-1-amine, or the like can be used.

### Structure Example 2 of Composite Material

For example, a composite material containing a substance having an acceptor property, a material having a hole-transport property, and a fluoride of an alkali metal or a fluoride of an alkaline earth metal can be used as the material having a hole-injection property. In particular, a composite material in which the proportion of fluorine atoms is higher than or equal to 20% can be suitably used. Thus, the refractive index of the layer 104 can be reduced. Alternatively, a layer with a low refractive index can be formed inside the light-emitting device 150. Alternatively, the external quantum efficiency of the light-emitting device 150 can be improved.

Note that this embodiment can be combined as appropriate with any of the other embodiments described in this specification.

### Embodiment 5

In this embodiment, a structure of the light-emitting device 150 that can be used for the display panel of one embodiment of the present invention will be described with reference to FIG. 24A. Note that the structure that can be used for the light-emitting device 150 can be used for, for example, the light-emitting device 550B(i,j), the light-emitting device 550G(i,j), or the light-emitting device 550R(i,j) described in Embodiment 1.

### Structure Example of Light-Emitting Device 150

The light-emitting device 150 described in this embodiment includes the electrode 101, the electrode 102, the unit 103, and the layer 105. The electrode 102 includes a region overlapping with the electrode 101, and the unit 103 includes a region interposed between the electrode 101 and the electrode 102. The layer 105 includes a region interposed between the unit 103 and the electrode 102. For example, the structure described in Embodiment 3 can be used for the unit 103. In addition, the structure that can be used for the electrode 102 can be used for, for example, the electrode 552B(j), the electrode 552G(j), or the electrode 552R(j) described in Embodiment 1. The material that can be used for the layer 105 can be used for, for example, the layer 105B(j), the layer 105G(j), or the layer 105R(j) described in Embodiment 1.

### Structure Example of Electrode 102

For example, a conductive material can be used for the electrode 102. Specifically, a metal, an alloy, a conductive compound, a mixture of these, or the like can be used for the electrode 102. For example, a material with a lower work function than the electrode 101 can be suitably used for the electrode 102. Specifically, a material having a work function lower than or equal to 3.8 eV is preferably used.

For example, an element belonging to Group 1 of the periodic table, an element belonging to Group 2 of the periodic table, a rare earth metal, or an alloy containing any of these elements can be used for the electrode 102.

Specifically, lithium (Li), cesium (Cs), or the like; magnesium (Mg), calcium (Ca), strontium (Sr), or the like; europium (Eu), ytterbium (Yb), or the like or an alloy containing any of these (MgAg or AlLi) can be used for the electrode 102.

### Structure Example of Layer 105

For example, a material having an electron-injection property can be used for the layer 105. The layer 105 can also be referred to as an electron-injection layer.

Specifically, a substance having a donor property can be used for the layer 105. Alternatively, a material in which a substance having a donor property and a material having an electron-transport property are combined can be used for the layer 105. Alternatively, an electride can be used for the layer 105. This can facilitate the injection of electrons from the electrode 102, for example. Alternatively, not only a material having a low work function but also a material having a high work function can also be used for the electrode 102. Alternatively, a material used for the electrode 102 can be selected from a wide range of materials regardless of its work function. Specifically, Al, Ag, ITO, indium oxide-tin oxide containing silicon or silicon oxide, and the like can be used for the electrode 102. Alternatively, the driving voltage of the light-emitting device can be reduced.

### Donor Substance

For example, an alkali metal, an alkaline earth metal, a rare earth metal, or a compound thereof (an oxide, a halide, a carbonate, or the like) can be used for the substance having a donor property. Alternatively, an organic compound such as tetrathianaphthacene (abbreviation: TTN), nickelocene, or decamethylnickelocene can be used as the substance having a donor property.

### Structure Example 1 of Composite Material

A material composed of two or more kinds of substances can be used as the material having an electron-injection property. For example, a substance having a donor property and a material having an electron-transport property can be used for the composite material.

### Electron-Transport Material

For example, a metal complex or an organic compound having a π-electron deficient heteroaromatic ring skeleton can be used as the material having an electron-transport property.

For example, a material having an electron-transport property capable of being used for the unit 103 can be used as the composite material.

### Structure Example 2 of Composite Material

A material including a fluoride of an alkali metal in a microcrystalline state and a material having an electron-transport property can be used for the composite material. Alternatively, a material including a fluoride of an alkaline earth metal in a microcrystalline state and a material having an electron-transport property can be used for the composite material. In particular, a composite material including a fluoride of an alkali metal or a fluoride of an alkaline earth metal at 50 wt % or higher can be suitably used. Alternatively, a composite material including an organic compound having a bipyridine skeleton can be suitably used. Thus, the refractive index of the layer 105 can be reduced. The external quantum efficiency of the light-emitting device can be improved.

### Electride

For example, a substance obtained by adding electrons at high concentration to an oxide where calcium and aluminum are mixed, or the like can be used as the material having an electron-injection property.

Note that this embodiment can be combined with any of the other embodiments described in this specification as appropriate.

### Embodiment 6

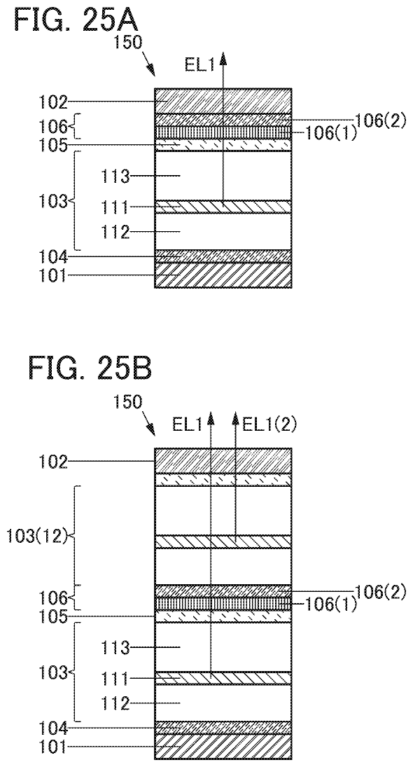

In this embodiment, a structure of the light-emitting device 150 that can be used for the display panel of one embodiment of the present invention is described with reference to FIG. 25A.

FIG. 25A is a cross-sectional view illustrating a structure of a light-emitting device that can be used for the display panel of one embodiment of the present invention.

### Structure Example of Light-Emitting Device 150

The light-emitting device 150 described in this embodiment includes the electrode 101, the electrode 102, the unit 103, and the layer 106 (see FIG. 25A). The electrode 102 includes a region overlapping with the electrode 101, and the unit 103 includes a region interposed between the electrode 101 and the electrode 102. The layer 106 includes a region interposed between the unit 103 and the electrode 102.

### Structure Example of Layer 106

The layer 106 includes a layer 106(1) and a layer 106(2). The layer 106(2) includes a region interposed between the layer 106(1) and the electrode 102.

### Structure Example of Layer 106(1)

For example, a material having an electron-transport property can be used for the layer 106(1). The layer 106(1) can be referred to as an electron-relay layer. With the use of the layer 106(1), a layer that is on the anode side and in contact with the layer 106(1) can be kept away from a layer that is on the cathode side and in contact with the layer 106(1). Interaction between the layer that is on the anode side and in contact with the layer 106(1) and the layer that is on the cathode side and in contact with the layer 106(1) can be reduced. Electrons can be smoothly supplied to the layer that is on the anode side and in contact with the layer 106(1).

A substance whose LUMO level is positioned between the LUMO level of the substance having an acceptor property included in the layer that is on the anode side and in contact with the layer 106(1) and the LUMO level of the substance included in the layer that is on the cathode side and in contact with the layer 106(1) can be suitably used for the layer 106(1).

For example, a material having a LUMO level in a range higher than or equal to −5.0 eV, preferably higher than or equal to −5.0 eV and lower than or equal to −3.0 eV, can be used for the layer 106(1).

Specifically, a phthalocyanine-based material can be used for the layer 106(1). Alternatively, a metal complex having a metal-oxygen bond and an aromatic ligand can be used for the layer 106(1).

### Structure Example of Layer 106(2)

For example, a material that supplies electrons to the anode side and supplies holes to the cathode side when voltage is applied can be used for the layer 106(2). Specifically, electrons can be supplied to the unit 103 that is positioned on the anode side. The layer 106(2) can be referred to as a charge-generation layer.

Specifically, a material having a hole-injection property capable of being used for the layer 104 can be used for the layer 106(2). For example, a composite material can be used for the layer 106(2). Alternatively, for example, a stacked film in which a film including the composite material and a film including a material having a hole-transport property are stacked can be used for the layer 106(2).

Note that this embodiment can be combined with any of the other embodiments described in this specification as appropriate.

### Embodiment 7

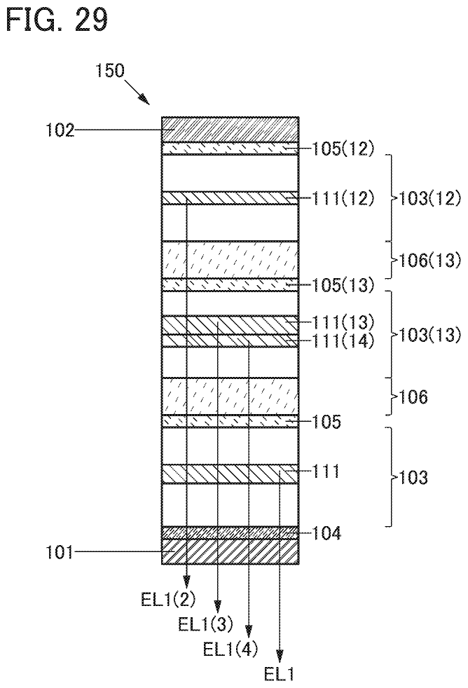

In this embodiment, a structure of the light-emitting device 150 that can be used for the display panel of one embodiment of the present invention is described with reference to FIG. 25B and FIG. 29.

FIG. 25B is a cross-sectional view illustrating a structure of a light-emitting device that can be used for the display panel of one embodiment of the present invention, which is different from the structure illustrated in FIG. 25A.

FIG. 29 is a cross-sectional view illustrating a structure of a light-emitting device that can be used for the display panel of one embodiment of the present invention, which is different from the structure illustrated in FIG. 25B.

### Structure Example 1 of Light-Emitting Device 150

The light-emitting device 150 described in this embodiment includes the electrode 101, the electrode 102, the unit 103, the layer 106, and a unit 103(12) (see FIG. 25B). The electrode 102 includes a region overlapping with the electrode 101, the unit 103 includes a region interposed between the electrode 101 and the electrode 102, and the layer 106 includes a region interposed between the unit 103 and the electrode 102. The unit 103(12) includes a region interposed between the layer 106 and the electrode 102, and the unit 103(12) has a function of emitting light EL1(2).

A structure including the layer 106 and a plurality of units is referred to as a stacked light-emitting device or a tandem light-emitting device in some cases. This structure can obtain light emission at high luminance while the current density is kept low. Alternatively, the reliability can be increased. Alternatively, the driving voltage can be reduced in comparison with that of the light-emitting device with the same luminance. Alternatively, power consumption can be reduced.

### Structure Example of Unit 103(12)

The structure that can be used for the unit 103 can also be used for the unit 103(12). In other words, the light-emitting device 150 includes a plurality of units that are stacked. Note that the number of stacked units is not limited to two, and three or more units can be stacked.

The same structure as the unit 103 can be used for the unit 103(12). Alternatively, a structure different from the unit 103 can be used for the unit 103(12).

For example, a structure which exhibits a different emission color from that of the unit 103 can be used for the unit 103(12). Specifically, the unit 103 emitting red light and green light and the unit 103(12) emitting blue light can be used. With this structure, a light-emitting device emitting light of a desired color can be provided. A light-emitting device emitting white light can be provided, for example.

### Structure Example of Layer 106

The layer 106 has a function of supplying electrons to one of the unit 103 and the unit 103(12) and supplying holes to the other. For example, the layer 106 described in Embodiment 6 can be used.

### Structure Example 2 of Light-Emitting Device 150

The light-emitting device 150 described in this embodiment includes the electrode 101, the electrode 102, the unit 103, the layer 106, the unit 103(12), a unit 103(13), a layer 105(12), a layer 105(13), and a layer 106(13) (see FIG. 29).

The light-emitting device 150 illustrated in FIG. 29 is different from the light-emitting device 150 illustrated in FIG. 25B in that the unit 103(13), the layer 105(13), and the layer 106(13) are provided between the layer 106 and the unit 103(12).

The layer 111 has a function of emitting light EL1, a layer 111(12) has a function of emitting light EL1(2), a layer 111(13) has a function of emitting light EL1(3), and a layer 111(14) has a function of emitting light EL1(4).

For example, a light-emitting material that emits blue light can be used for the layer 111 and the layer 111(12). For example, a light-emitting material that emits yellow light can be used for the layer 111(13). For example, a light-emitting material that emits red light can be used for the layer 111(14).

For example, a structure that can be used for the unit 103 can be used for the unit 103(13), a structure that can be used for the layer 105 can be used for the layer 105(12) and the layer 105(13), and a structure that can be used for the layer 106 can be used for the layer 106(13).

### Method for Manufacturing Light-Emitting Device 150

For example, each layer of the electrode 101, the electrode 102, the unit 103, the layer 106, and the unit 103(12) can be formed by a dry process, a wet process, an evaporation method, a droplet discharge method, a coating method, a printing method, or the like. Different methods can be used to form the components.

Specifically, the light-emitting device 150 can be manufactured with a vacuum evaporation machine, an ink-jet machine, a coating machine such as a spin coater, a gravure printing machine, an offset printing machine, a screen printing machine, or the like.

For example, the electrode can be formed by a wet process or a sol-gel method using a paste of a metal material. An indium oxide-zinc oxide film can be formed by a sputtering method using a target obtained by adding, to indium oxide, zinc oxide at higher than or equal to 1 wt % and lower than or equal to 20 wt %. An indium oxide film containing tungsten oxide and zinc oxide (IWZO) can be formed by a sputtering method using a target containing, with respect to indium oxide, tungsten oxide at higher than or equal to 0.5 wt % and lower than or equal to 5 wt % and zinc oxide at higher than or equal to 0.1 wt % and lower than or equal to 1 wt %.

Note that this embodiment can be combined with any of the other embodiments described in this specification as appropriate.

### Embodiment 8

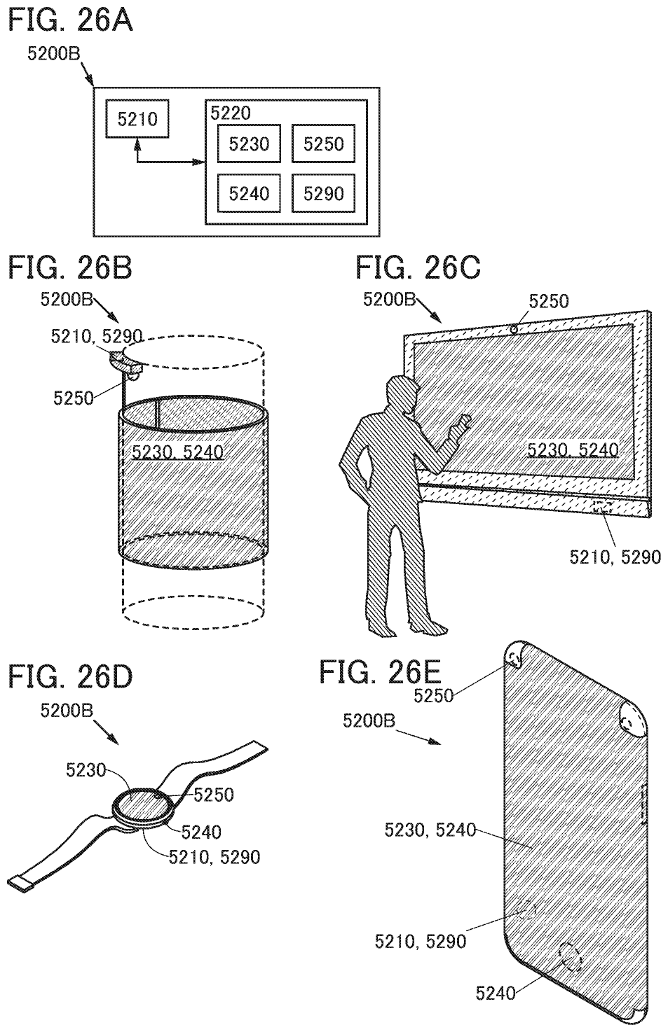

In this embodiment, structures of a data processing device of one embodiment of the present invention will be described with reference to FIG. 26 to FIG. 28.

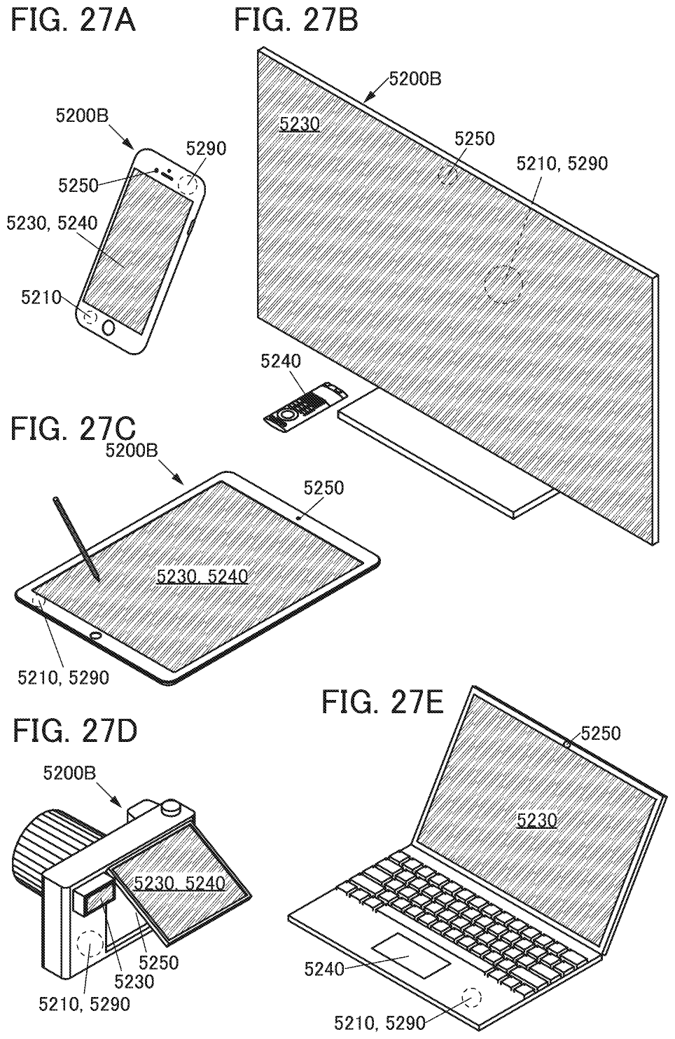

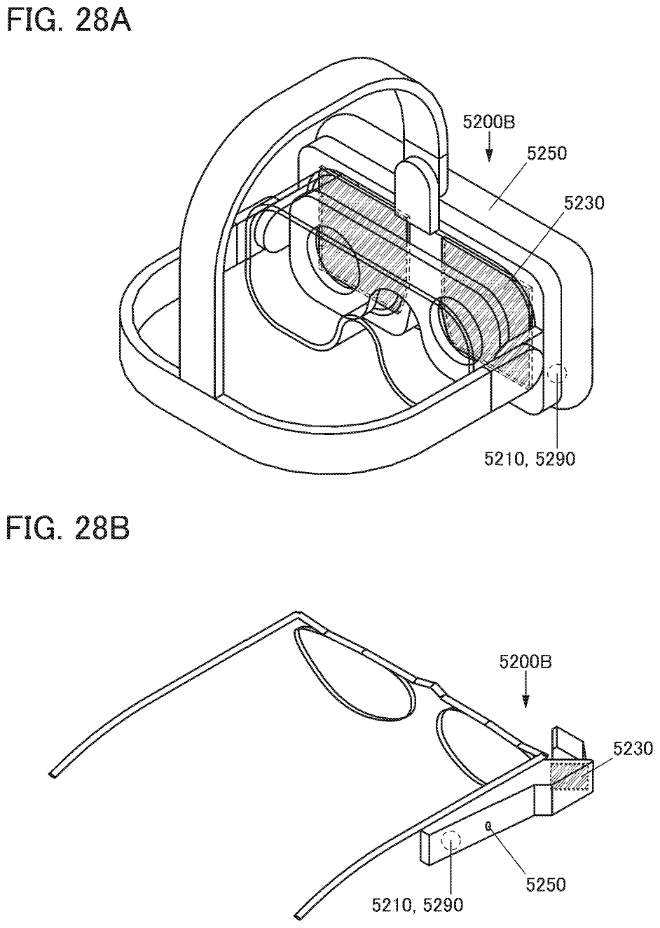

FIG. 26 to FIG. 28 are diagrams illustrating structures of the data processing device of one embodiment of the present invention. FIG. 26A is a block diagram of the data processing device, and FIG. 26B to FIG. 26E are perspective views illustrating structures of the data processing device. FIG. 27A to FIG. 27E are perspective views illustrating structures of the data processing device. FIG. 28A and FIG. 28B are perspective views illustrating structures of the data processing device.

### Data Processing Device

A data processing device 5200B described in this embodiment includes an arithmetic device 5210 and an input/output device 5220 (see FIG. 26A).

The arithmetic device 5210 has a function of being supplied with operation information and a function of supplying image information on the basis of the operation information.

The input/output device 5220 includes a display portion 5230, an input portion 5240, a sensing portion 5250, and a communication portion 5290 and has a function of supplying operation information and a function of being supplied with image information. The input/output device 5220 also has a function of supplying sensing information, a function of supplying communication information, and a function of being supplied with communication information.

The input portion 5240 has a function of supplying operation information. For example, the input portion 5240 supplies operation information on the basis of operation by a user of the data processing device 5200B.

Specifically, a keyboard, a hardware button, a pointing device, a touch sensor, an illuminance sensor, an imaging device, an audio input device, an eye-gaze input device, an attitude detection device, or the like can be used as the input portion 5240.

The display portion 5230 includes a display panel and has a function of displaying image information. For example, the display panel described in Embodiment 1 can be used for the display portion 5230.

The sensing portion 5250 has a function of supplying sensing information. For example, the sensing portion 5250 has a function of sensing a surrounding environment where the data processing device is used and supplying sensing information.

Specifically, an illuminance sensor, an imaging device, an attitude detection device, a pressure sensor, a human motion sensor, or the like can be used as the sensing portion 5250.

The communication portion 5290 has a function of being supplied with communication information and a function of supplying communication information. For example, the communication portion 5290 has a function of being connected to another electronic device or a communication network through wireless communication or wired communication. Specifically, the communication portion 5290 has a function of wireless local area network communication, telephone communication, near field communication, or the like.

### Structure Example 1 of Data Processing Device

For example, the display portion 5230 can have an outer shape along a cylindrical column or the like (see FIG. 26B). In addition, the data processing device has a function of changing its display method in accordance with the illuminance of a usage environment. Furthermore, the data processing device has a function of changing displayed content in response to sensed existence of a person. This allows the data processing device to be provided on a column of a building, for example. The data processing device can display advertising, guidance, or the like. The data processing device can be used for digital signage or the like.

### Structure Example 2 of Data Processing Device

For example, the data processing device has a function of generating image information on the basis of the path of a pointer used by a user (see FIG. 26C). Specifically, the display panel with a diagonal size of 20 inches or longer, preferably 40 inches or longer, further preferably 55 inches or longer can be used. Alternatively, a plurality of display panels can be arranged and used as one display region. Alternatively, a plurality of display panels can be arranged and used as a multiscreen. Thus, the data processing device can be used for an electronic blackboard, an electronic bulletin board, digital signage, or the like.

### Structure Example 3 of Data Processing Device

The data processing device can receive information from another device, and the information can be displayed on the display portion 5230 (see FIG. 26D). Several options can be displayed. The user can choose some from the options and send a reply to a transmitter of the information. For example, the data processing device has a function of changing its display method in accordance with the illuminance of a usage environment. Thus, for example, the power consumption of a portable electronic device can be reduced. Alternatively, for example, a portable electronic device can display an image so as to be suitably used even in an environment under strong external light, e.g., outdoors in fine weather.

### Structure Example 4 of Data Processing Device

For example, the display portion 5230 has a surface gently curved along a side surface of a housing (see FIG. 26E). The display portion 5230 includes a display panel, and the display panel has a function of performing display on the front surface, the side surfaces, the top surface, and the rear surface, for example. Thus, for example, a mobile phone can display information not only on its front surface but also on its side surfaces, its top surface, and its rear surface.

### Structure Example 5 of Data Processing Device

For example, the data processing device can receive information via the Internet and display the information on the display portion 5230 (see FIG. 27A). A created message can be checked on the display portion 5230. The created message can be sent to another device. The data processing device has a function of changing its display method in accordance with the illuminance of a usage environment, for example. Thus, the power consumption of a smartphone can be reduced. Alternatively, for example, a smartphone can display an image so as to be suitably used even in an environment under strong external light, e.g., outdoors in fine weather.

### Structure Example 6 of Data Processing Device

A remote controller can be used as the input portion 5240 (see FIG. 27B). For example, the data processing device can receive information from a broadcast station or via the Internet and display the information on the display portion 5230. An image of a user can be captured using the sensing portion 5250. The image of the user can be transmitted. The data processing device can acquire a viewing history of the user and provide it to a cloud service. The data processing device can acquire recommendation information from a cloud service and display the information on the display portion 5230. A program or a moving image can be displayed on the basis of the recommendation information. For example, the data processing device has a function of changing its display method in accordance with the illuminance of a usage environment. Accordingly, for example, a television system can display an image to be suitably used even when irradiated with strong external light that enters a room in fine weather.

### Structure Example 7 of Data Processing Device

For example, the data processing device can receive educational materials via the Internet and display them on the display portion 5230 (see FIG. 27C). An assignment can be input with the input portion 5240 and sent via the Internet. A corrected assignment or the evaluation of the assignment can be obtained from a cloud service and displayed on the display portion 5230. Suitable educational materials can be selected on the basis of the evaluation and displayed.

For example, the display portion 5230 can perform display using an image signal received from another data processing device. When the data processing device is placed on a stand or the like, the display portion 5230 can be used as a sub-display. Thus, for example, a tablet computer can display an image to be suitably used even in an environment under strong external light, e.g., outdoors in fine weather.

### Structure Example 8 of Data Processing Device

The data processing device includes, for example, a plurality of display portions 5230 (see FIG. 27D). For example, the display portion 5230 can display an image that the sensing portion 5250 is capturing. A captured image can be displayed on the sensing portion. A captured image can be decorated using the input portion 5240. A message can be attached to a captured image. A captured image can be transmitted via the Internet. The data processing device has a function of changing its shooting conditions in accordance with the illuminance of a usage environment. Accordingly, for example, a digital camera can display a subject in such a manner that an image is suitably viewed even in an environment under strong external light, e.g., outdoors in fine weather.

### Structure Example 9 of Data Processing Device

For example, the data processing device of this embodiment is used as a master and another data processing device is used as a slave, whereby the other data processing device can be controlled (see FIG. 27E). As another example, part of image information can be displayed on the display portion 5230 and another part of the image information can be displayed on a display portion of another data processing device. Image signals can be supplied. With the communication portion 5290, information to be written can be obtained from an input portion of another data processing device. Thus, a large display region can be utilized by using a portable personal computer, for example.

### Structure Example 10 of Data Processing Device

The data processing device includes, for example, the sensing portion 5250 that senses an acceleration or a direction (see FIG. 28A). The sensing portion 5250 can supply information on the position of the user or the direction in which the user faces. The data processing device can generate image information for the right eye and image information for the left eye in accordance with the position of the user or the direction in which the user faces. The display portion 5230 includes a display region for the right eye and a display region for the left eye. Thus, a virtual reality image that gives the user a sense of immersion can be displayed on a goggles-type data processing device, for example.

### Structure Example 11 of Data Processing Device

The data processing device includes, for example, an imaging device and the sensing portion 5250 that senses an acceleration or a direction (see FIG. 28B). The sensing portion 5250 can supply information on the position of the user or the direction in which the user faces. The data processing device can generate image information in accordance with the position of the user or the direction in which the user faces. Accordingly, the information can be shown together with a real-world scene, for example. An augmented reality image can be displayed on a glasses-type data processing device.

Note that this embodiment can be combined with any of the other embodiments described in this specification as appropriate.

### REFERENCE NUMERALS

ANO: conductive film, CFB: coloring layer, CFG: coloring layer, CFR: coloring layer, CFS: gap, C21: capacitor, C22: capacitor, G1: conductive film, G2: conductive film, M21: transistor, N21: node, N22: node, S1g: conductive film, S2g: conductive film, SW21: switch, SW22: switch, SW23: switch, VCOM2: conductive film, WL1: sidewall, WL2: sidewall, 101: electrode, 102: electrode, 103: unit, 103B: unit, 103B2: unit, 103G: unit, 103G2: unit, 103R: unit, 103R2: unit, 104: layer, 104B: layer, 104G: layer, 104R: layer, 104S: gap, 105: layer, 105B: layer, 105G: layer, 105R: layer, 106: layer, 106(1): layer, 106(2): layer, 106(13): layer, 106B: intermediate layer, 106G: intermediate layer, 106R: intermediate layer, 106S: gap, 111: layer, 111B: layer, 111G: layer, 111R: layer, 112: layer, 113: layer, 150: light-emitting device, 231: display region, 501C: insulating film, 501D: insulating film, 504: conductive film, 506: insulating film, 508: semiconductor film, 508A: region, 508B: region, 508C: region, 510: base material, 512A: conductive film, 512B: conductive film, 516: insulating film, 516A: insulating film, 516B: insulating film, 518: insulating film, 519B: terminal, 520: functional layer, 520T: region, 524: conductive film, 528: partition, 528B: opening portion, 528G: opening portion, 528R: opening portion, 550B: light-emitting device, 550G: light-emitting device, 550R: light-emitting device, 551B: electrode, 551G: electrode, 551R: electrode, 552: electrode, 552B: electrode, 552G: electrode, 552R: electrode, 573: insulating film, 573A: insulating film, 573B: insulating film, 573C: insulating film, 573D: insulating film, 573E: insulating film, 573F: insulating film, 591B: opening portion, 591G: opening portion, 700: display panel, 705: insulating layer, 770: base material, 1032: unit, 5200B: data processing device, 5210: arithmetic device, 5220: input/output device, 5230: display portion, 5240: input portion, 5250: sensing portion, 5290: communication portion

1. A display panel comprising:
a first light-emitting device;
a second light-emitting device; and
a partition,
wherein the first light-emitting device comprises a first electrode, a second electrode, and a first layer,
wherein the first layer comprises a region interposed between the second electrode and the first electrode,
wherein the first layer comprises a first material having a hole-transport property and a first substance having an acceptor property,
wherein the first layer has an electrical resistivity greater than or equal to 1×10² [Ω cm] and less than or equal to 1×10⁸ [Ω cm],
wherein the second light-emitting device comprises a third electrode, a fourth electrode, and a second layer,
wherein the second layer comprises a region interposed between the fourth electrode and the third electrode,
wherein the second layer comprises the first material having the hole-transport property and the first substance having the acceptor property,
wherein the second layer comprises a first gap between the second layer and the first layer,
wherein the first gap comprises a region overlapping with the partition, and
wherein the first gap prevents electrical continuity between the first layer and the second layer.

2. A display panel comprising:
a first light-emitting device;
a second light-emitting device; and
a partition,
wherein the first light-emitting device comprises a first electrode, a second electrode, a first unit, and a first layer,
wherein the second electrode overlaps with the first electrode,
wherein the first unit comprises a region interposed between the second electrode and the first electrode,
wherein the first layer comprises a region interposed between the first unit and the first electrode,
wherein the first layer comprises a first material having a hole-transport property and a first substance having an acceptor property,
wherein the first layer has an electrical resistivity greater than or equal to 1×10² [Ω cm] and less than or equal to 1×10⁸ [Ω cm],
wherein the second light-emitting device comprises a third electrode, a fourth electrode, a second unit, and a second layer,
wherein the fourth electrode overlaps with the third electrode,
wherein the second unit comprises a region interposed between the fourth electrode and the third electrode,
wherein the second layer comprises a region interposed between the second unit and the first electrode,
wherein the second layer comprises the first material having the hole-transport property and the first substance having the acceptor property,
wherein the second layer comprises a first gap between the second layer and the first layer,
wherein the partition comprises a first opening portion and a second opening portion,
wherein the first opening portion overlaps with the first electrode,
wherein the second opening portion overlaps with the third electrode, and
wherein the partition overlaps with the first gap between the first opening portion and the second opening portion.

3. The display panel according to claim 2,
wherein the first light-emitting device comprises a third unit and a first intermediate layer,
wherein the third unit comprises a region interposed between the second electrode and the first unit,
wherein the first intermediate layer comprises a region interposed between the third unit and the first unit,
wherein the first intermediate layer comprises a second material having a hole-transport property and a second substance having an acceptor property,
wherein the first intermediate layer has an electrical resistivity greater than or equal to 1×10² [Ω cm] and less than or equal to 1×10⁸ [Ω cm],
wherein the second light-emitting device comprises a fourth unit and a second intermediate layer,
wherein the fourth unit comprises a region interposed between the fourth electrode and the second unit,
wherein the second intermediate layer comprises a region interposed between the fourth unit and the second unit,
wherein the second intermediate layer comprises the second material having the hole-transport property and the second substance having the acceptor property,
wherein the second intermediate layer comprises a second gap between the second intermediate layer and the first intermediate layer, and
wherein the partition overlaps with the second gap between the first opening portion and the second opening portion.

4. The display panel according to claim 1,
wherein the first material having the hole-transport property is an aromatic amine compound or an organic compound comprising a π-electron rich heteroaromatic ring, and
wherein the first substance having the acceptor property is an organic compound comprising fluorine or a cyano group or a transition metal oxide.

5. The display panel according to claim 1, further comprising a first insulating film,
wherein the second electrode is interposed between the first insulating film and the first electrode, and
wherein the fourth electrode is interposed between the first insulating film and the third electrode.

6. The display panel according to claim 5,
wherein the first layer comprises a first sidewall,
wherein the second layer comprises a second sidewall,
wherein the second sidewall faces the first sidewall,
wherein the first gap is interposed between the second sidewall and the first sidewall, and
wherein the first insulating film is in contact with the first sidewall and the second sidewall.

7. The display panel according to claim 5, wherein the first insulating film is in contact with the partition.

8. The display panel according to claim 5,
wherein the first insulating film comprises a second insulating film and a third insulating film,
wherein the second insulating film is interposed between the third insulating film and the second electrode,
wherein the second insulating film is interposed between the third insulating film and the fourth electrode,
wherein the second insulating film comprises oxygen and aluminum, and
wherein the third insulating film comprises nitrogen and silicon.

9. The display panel according to claim 8,
wherein the partition is in contact with the second insulating film, and
wherein the partition comprises nitrogen and silicon.

10. The display panel according to claim 2, further comprising an insulating layer,
wherein the insulating layer fills the first gap, and
wherein the insulating layer fills a space between the first unit and the second unit.

11. The display panel according to claim 3, further comprising:
a first coloring layer; and
a second coloring layer,
wherein the first coloring layer overlaps with the first light-emitting device,
wherein the second coloring layer overlaps with the second light-emitting device,
wherein the second coloring layer comprises a third gap between the second coloring layer and the first coloring layer,
wherein the second coloring layer comprises a first sidewall facing the first coloring layer,
wherein the fourth unit comprises a second sidewall continuous with the first sidewall, and
wherein the second unit comprises a third sidewall continuous with the second sidewall.

12. The display panel according to claim 1, further comprising:
a functional layer;
a first pixel; and
a second pixel,
wherein the first pixel comprises the first light-emitting device and a pixel circuit,
wherein the functional layer comprises the pixel circuit and a region having a light-transmitting property,
wherein the pixel circuit is electrically connected to the first light-emitting device,
wherein the region having the light-transmitting property transmits light emitted from the first light-emitting device, and
wherein the second pixel comprises the second light-emitting device.

13. A data processing device comprising:
one or more of a keyboard, a hardware button, a pointing device, a touch sensor, an illuminance sensor, an imaging device, an audio input device, an eye-gaze input device, and an attitude detection device; and
the display panel according to claim 1.

14. A method for manufacturing a display panel, the method comprising the steps of:
forming a first electrode and a second electrode;
forming a partition between the first electrode and the second electrode;
forming a first layer over the first electrode and the second electrode;
forming a first unit over the first layer;
forming a third electrode over the first unit;
removing the first layer, the first unit, and the third electrode over the second electrode by a photoetching method to form a first light-emitting device;
forming a second layer over the third electrode and the second electrode;
forming a second unit over the second layer;
forming a fourth electrode over the second unit; and
removing the second layer, the second unit, and the fourth electrode over the third electrode by a photoetching method to form a second light-emitting device separated from the first light-emitting device.

15. A method for manufacturing a display panel, the method comprising the steps of:
forming a first electrode and a second electrode;
forming a partition between the first electrode and the second electrode;
forming a layer over the first electrode and the second electrode;
forming a first unit over the layer;
forming an intermediate layer over the first unit;
forming a second unit over the intermediate layer;
forming a conductive film over the second unit; and
removing the layer, the first unit, the intermediate layer, the second unit, and the conductive film over the partition by a photoetching method to form a first light-emitting device and a second light-emitting device.

16. The display panel according to claim 2,
wherein the first material having the hole-transport property is an aromatic amine compound or an organic compound comprising a π-electron rich heteroaromatic ring, and
wherein the first substance having the acceptor property is an organic compound comprising fluorine or a cyano group or a transition metal oxide.

17. The display panel according to claim 2, further comprising a first insulating film,
wherein the second electrode is interposed between the first insulating film and the first electrode, and
wherein the fourth electrode is interposed between the first insulating film and the third electrode.

18. The display panel according to claim 17,
wherein the first layer comprises a first sidewall,
wherein the second layer comprises a second sidewall,
wherein the second sidewall faces the first sidewall,
wherein the first gap is interposed between the second sidewall and the first sidewall, and
wherein the first insulating film is in contact with the first sidewall and the second sidewall.

19. The display panel according to claim 17, wherein the first insulating film is in contact with the partition.

20. The display panel according to claim 17,
wherein the first insulating film comprises a second insulating film and a third insulating film,
wherein the second insulating film is interposed between the third insulating film and the second electrode,
wherein the second insulating film is interposed between the third insulating film and the fourth electrode,
wherein the second insulating film comprises oxygen and aluminum, and
wherein the third insulating film comprises nitrogen and silicon.

21. The display panel according to claim 20,
wherein the partition is in contact with the second insulating film, and
wherein the partition comprises nitrogen and silicon.

22. The display panel according to claim 2, further comprising:
a functional layer;
a first pixel; and
a second pixel,
wherein the first pixel comprises the first light-emitting device and a pixel circuit,
wherein the functional layer comprises the pixel circuit and a region having a light-transmitting property,
wherein the pixel circuit is electrically connected to the first light-emitting device,
wherein the region having the light-transmitting property transmits light emitted from the first light-emitting device, and
wherein the second pixel comprises the second light-emitting device.

23. A data processing device comprising:
one or more of a keyboard, a hardware button, a pointing device, a touch sensor, an illuminance sensor, an imaging device, an audio input device, an eye-gaze input device, and an attitude detection device; and
the display panel according to claim 2.
